(19) United States
(12) Patent Application Publication
(10) Pub. No.: US 2026/0239693 A1
(43) Pub. Date: Aug. 13, 2026

(54) SOURCE/DRAIN FEATURES FOR STACKED MULTI-GATE DEVICE

(71) Applicant: Taiwan Semiconductor Manufacturing Company, Ltd., Hsinchu (TW)

(72) Inventor: Winnie Victoria Wei-Ning Chen, Zhubei City (TW)

(21) Appl. No.: 19/277,238

(22) Filed: Jul. 22, 2025

Related U.S. Application Data
(63) Continuation of application No. 18/352,708, filed on Jul. 14, 2023.

(51) Int. Cl. H10D 62/13; H10D 30/01; H10D 30/43; H10D 30/67; H10D 62/10; H10D 64/01; H10D 84/01; H10D 84/03; H10D 84/85

(52) U.S. Cl. CPC H10D 62/151; H10D 30/014; H10D 30/43; H10D 30/6735; H10D 30/6757; H10D 62/121; H10D 64/017; H10D 84/0167; H10D 84/017; H10D 84/0188; H10D 84/038; H10D 84/85

(57) ABSTRACT

Semiconductor structures and processes of forming the same are provided. A semiconductor structure according to the present disclosure includes a substrate, a first source/drain feature disposed on the substrate, a first contact etch stop layer disposed on the first source/drain feature, a first dielectric layer disposed over the first CESL, an etch stop layer (ESL) disposed on and in contact with the first CESL and the first dielectric layer, a second source/drain feature disposed over the ESL, a second (CESL) disposed on the second source/drain feature, a second dielectric layer disposed over the second CESL. The first source/drain feature includes silicon and an n-type dopant and the second source/drain feature includes silicon germanium and a p-type dopant.

### PRIORITY DATA

This application is a continuation application of U.S. patent application Ser. No. 18/352,708, filed Jul. 14, 2023, which is hereby incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and multi-bridge-channel (MBC) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. The channel region of an MBC transistor may be formed from nanowires, nanosheets, other nanostructures, and/or other suitable structures. The shapes of the channel region have also given an MBC transistor alternative names such as a nanosheet transistor or a nanowire transistor.

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where multi-gate transistors are stacked vertically, one over the other.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming a semiconductor device having a vertical C-FET structure, according to one or more aspects of the present disclosure.

FIGS. 2-14 illustrate fragmentary cross-sectional views of a workpiece undergoing various fabrication processes in the method of FIG. 1, according to one or more aspects of the present disclosure.

FIG. 15 illustrates a flow chart of a method for forming a semiconductor device having a vertical C-FET structure, according to one or more aspects of the present disclosure.

FIGS. 16-31 illustrate fragmentary cross-sectional views of a workpiece undergoing various fabrication processes in the method of FIG. 15, according to one or more aspects of the present disclosure.

FIG. 32 illustrates a flow chart of a method for forming a multi-gate device, according to one or more aspects of the present disclosure.

FIGS. 33-44 illustrate fragmentary cross-sectional views of a workpiece undergoing various fabrication processes in the method of FIG. 32, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

A stacked multi-gate device refers to a semiconductor device that includes a bottom multi-gate device and a top multi-gate device stacked over the bottom multi-gate device. When the bottom multi-gate device and the top multi-gate device are of different conductivity types, the stacked multi-gate device may be a complementary field effect transistor (C-FET). The multi-gate devices in a C-FET may be FinFETs or MBC transistors. In some fabrication processes for C-FET devices, the two levels of multi-gate devices are formed sequentially. For example, source/drain features for the bottom multi-gate device are formed before source/drain features for the top multi-gate device. The epitaxial growth environments for the bottom source/drain features and the top source/drain features may not be exactly the same. In some instances, dielectric layers are first deposited over the bottom source/drain features before the top source/drain features are being deposited. The surfaces of the these dielectric layers may not be conducive for satisfactory epitaxial growth. As a result, the source/drain features grown thereon may be more defective than the other source/drain features that are grown with a large semiconductor surface. When the source/drain features serve to strain the channel, high defect density may deprive the ability of the source/drain features to exert stress. Even without a less-than-satisfactory epitaxial growth environment, there is need to efficiently enhance the channel-straining ability of source/drain features after their formation.

The present disclosure provides an after-deposition strain enhancement process for source/drain features for multi-gate devices or stacked multi-gate devices. In some examples where a source/drain feature that includes boron-doped silicon germanium is desired, epitaxial growth of the source/drain feature continues to a larger-than-usual thickness. The thick source/drain feature is then oxidized to form a surface oxide layer that includes silicon germanium oxide. The oxidation causes germanium condensation to mend defects in the source/drain feature by filling grain boundaries, stacking faults, or voids. The surface oxide layer is selectively removed. This process has been shown to restore or enhance the stress in the source/drain feature. Additionally, the mending of the defects allows the source/drain feature to have lower resistivity.

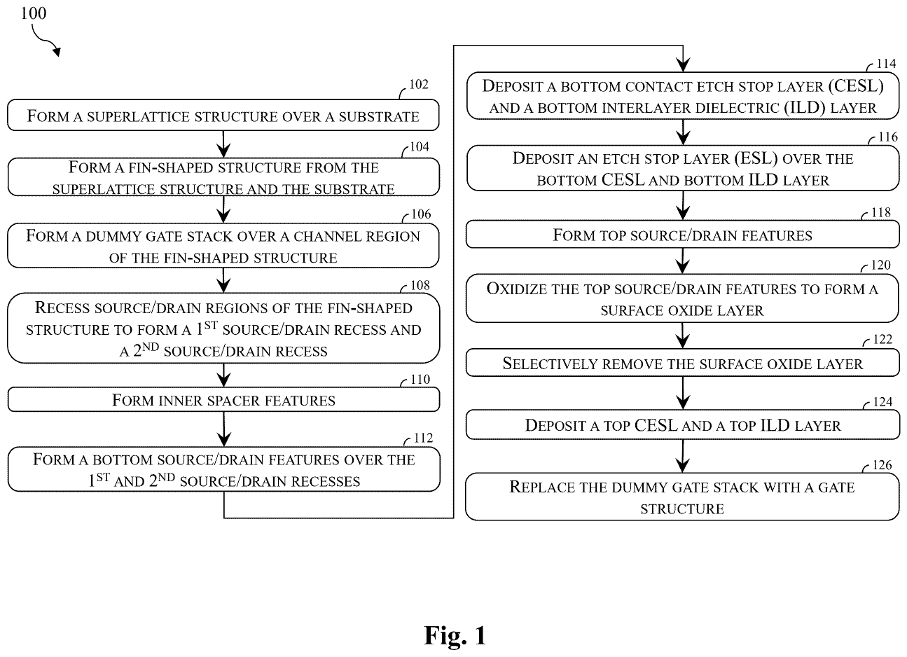

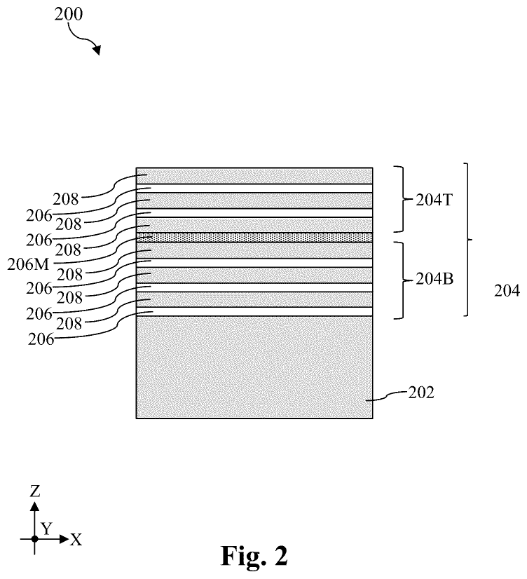

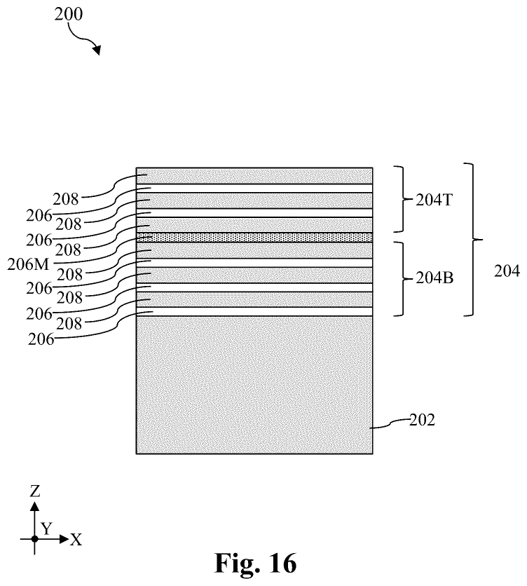

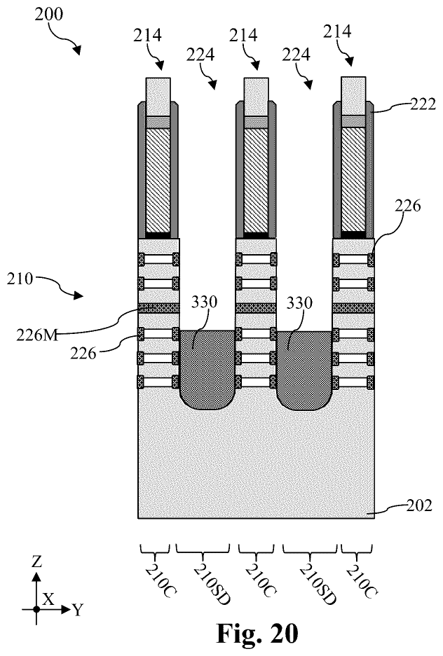

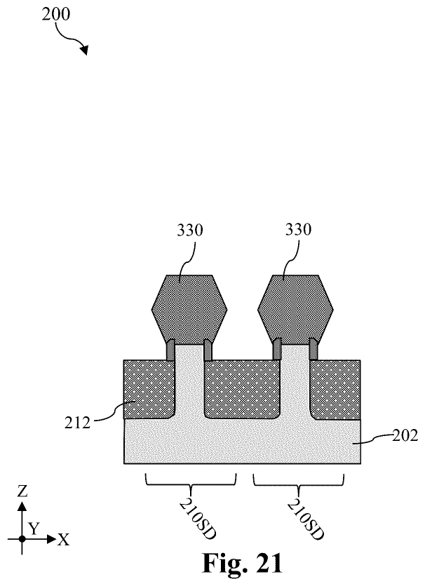

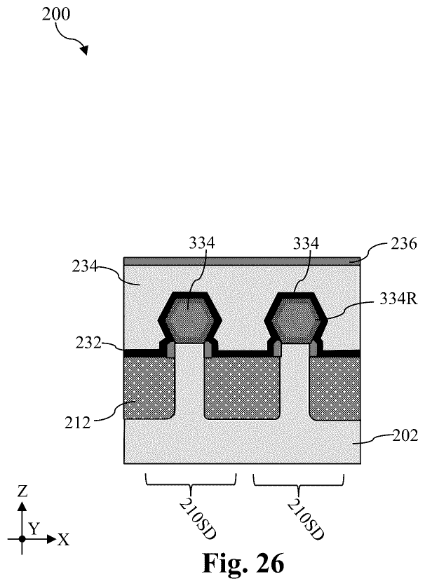

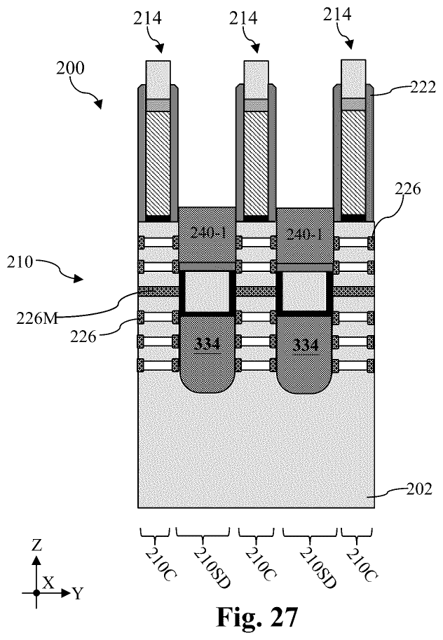

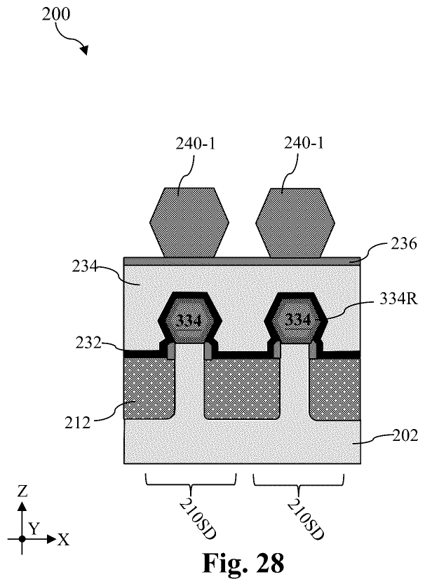

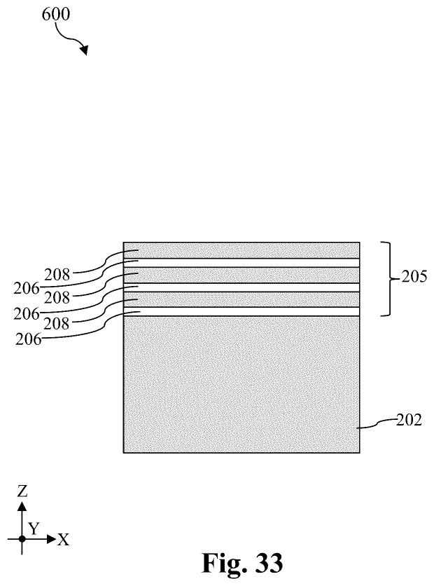

The various aspects of the present disclosure will now be described in more detail with reference to the figures. In that regard, FIGS. 1, 15 and 32 are flowcharts illustrating method 100, method 400 and method 500 for forming a semiconductor device according to various aspects of the present disclosure. Methods 100, 400 and 500 are merely examples and are not intended to limit the present disclosure to what is explicitly illustrated in methods 100, 400 and 500. Additional steps may be provided before, during and after method 100, 400 or 500, and some steps described can be replaced, eliminated, or moved around for additional embodiments of the method. Not all steps are described herein in detail for reasons of simplicity. Method 100 is described below in conjunction with FIGS. 2-14, which are fragmentary cross-sectional views of a workpiece 200 at different stages of fabrication according to embodiments of method 100. Method 400 is described below in conjunction with FIGS. 16-31, which are fragmentary cross-sectional views of a workpiece 200 at different stages of fabrication according to embodiments of method 400. Method 500 is described below in conjunction with FIGS. 33-44, which are fragmentary cross-sectional views of a workpiece 600 at different stages of fabrication according to embodiments of method 500. Because the workpiece 200 or the workpiece 600 will be fabricated into a semiconductor device 200 or a semiconductor device 600 upon conclusion of the fabrication processes, the workpiece 200 or workpiece 600 may be referred to as the semiconductor device 200 or the semiconductor device 600 as the context requires. Additionally, throughout the present application and across different embodiments, like reference numerals denote like features with similar structures and compositions, unless otherwise excepted. Source/drain region(s) may refer to a source or a drain, individually or collectively dependent upon the context.

Method 100 forms a C-FET where source/drain features of the top multi-gate device are strained using an oxidation process while source/drain features of the bottom multi-gate device do not undergo a similar oxidation process.

Referring to FIGS. 1 and 2, method 100 includes a block 102 where a superlattice structure 204 is formed over a substrate 202. In one embodiment, the substrate 202 may be a silicon (Si) substrate. In some other embodiments, the substrate 202 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 202 may also include an insulating layer, such as a silicon oxide layer, to have a silicon-on-insulator (SOI) structure. Although not explicitly shown in the figures, the substrate 202 may include an n-type well region and a p-type well region for fabrication of transistors of different conductivity types. When present, each of the n-type well and the p-type well is formed in the substrate 202 and includes a doping profile. An n-type well may include a doping profile of an n-type dopant, such as phosphorus (P) or arsenic (As). A p-type well may include a doping profile of a p-type dopant, such as boron (B). The doping in the n-type well and the p-type well may be formed using ion implantation or thermal diffusion and may be considered portions of the substrate 202. For ease of reference, the substrate 202 and structures formed thereon during the method 100 may be referred to as a workpiece 200.

At block 102, the superlattice structure 204 is deposited over the substrate 202 using an epitaxy process. Suitable epitaxy processes include vapor-phase epitaxy (VPE), ultra-high vacuum chemical vapor deposition (UHV-CVD), molecular beam epitaxy (MBE), and/or other suitable processes. The superlattice structure 204 includes a plurality of channel layers 208 interleaved by a plurality of sacrificial layers 206. The channel layers 208 and the sacrificial layers 206 may have different semiconductor compositions. In some implementations, the channel layers 208 are formed of silicon (Si) and sacrificial layers 206 are formed of silicon germanium (SiGe). In these implementations, the additional germanium content in the sacrificial layers 206 allow selective removal or recess of the sacrificial layers 206 without substantial damages to the channel layers 208. The sacrificial layers 206 and the channel layers 208 are deposited alternatingly, one-after-another, to form the superlattice structure 204.

The channel layers 208 in the bottom portion of the superlattice structure 204 will provide channel members of a bottom MBC transistor, and the channel layers 208 in the top portion of the superlattice structure 204 will provide channel members of a top MBC transistor. The term “channel member(s)” is used herein to designate any material portion for channel(s) in a transistor with nanoscale dimensions, and having an elongate shape, regardless of the cross-sectional shape of this portion. Channel members may come in forms of nanowires, nanosheet, or other nanostructures and may have cross-sections that are circular, oval, race-track shaped, rectangular, or square. For ease of references, the superlattice structure 204 may be vertically divided into a bottom portion 204B and a top portion 204T over the middle portion 204M, with a middle sacrificial layer 206M sandwiched in between. The middle sacrificial layer 206M and the other sacrificial layers may have different germanium contents. In some embodiments, a germanium content of the middle sacrificial layer 206M may be greater than a germanium content of the other sacrificial layers 206 such that the entirety of the middle sacrificial layer 206M may be selectively removed during the formation of inner spacer recesses.

It is noted that the superlattice structure 204 in FIG. 2 includes six (6) layers of the channel layers 208 interleaved by six (6) layers of sacrificial layers 206, which is for illustrative purposes only and not intended to be limiting beyond what is specifically recited in the claims. It can be appreciated that any number of the channel layers 208 can be included in the superlattice structure 204 and distributed between the bottom portion and the top portion 204T. The number of layers depends on the desired number of channels members for the top MBC transistor and the bottom MBC transistor. In some embodiments, the number of the channel layers 208 in the superlattice structure 204 may be between 4 and 10. The thicknesses of the channel layers 208 and the sacrificial layers 206 may be selected based on device performance considerations of the bottom MBC transistor, the top MBC transistor, and the C-FET as a whole.

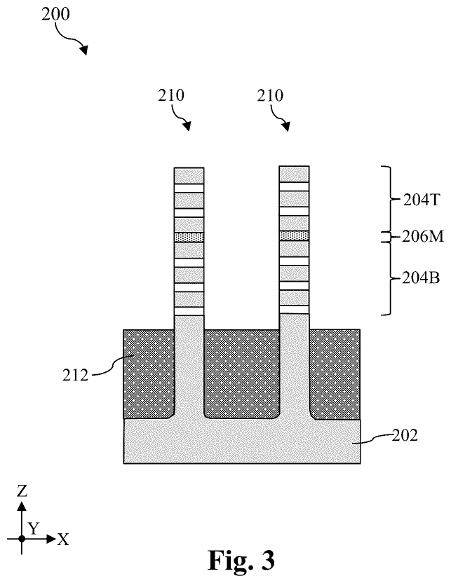

Referring to FIGS. 1 and 3, method 100 includes a block 104 where a fin-shaped structure 210 is formed from the superlattice structure 204 and a portion of the substrate 202. In some embodiments, the superlattice structure 204 and a portion of the substrate 202 are patterned to form the fin-shaped structure 210. For patterning purposes, a hard mask layer may be deposited over the superlattice structure 204. The hard mask layer may be a single layer or a multilayer. In one example, the hard mask layer includes a silicon oxide layer and a silicon nitride layer over the silicon oxide layer. As shown in FIG. 3, the fin-shaped structure 210 extends vertically along the Z direction from the substrate 202 and extends lengthwise along the Y direction. The fin-shaped structure 210 may be patterned using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used as an etch mask to etch the superlattice structure 204 and the substrate 202 to form the fin-shaped structure 210. The etching process may include dry etching, wet etching, reactive ion etching (RIE), and/or other suitable processes.

While not explicitly shown in FIG. 3, after the fin-shaped structure 210 is formed, an isolation feature 212 is formed around the fin-shaped structure 210 to separate the fin-shaped structure 210 from an adjacent fin-shaped structure (not explicitly shown). The isolation feature 212 may also be referred to as a shallow trench isolation (STI) feature 212. In an example process, a dielectric material for the isolation feature is deposited over the workpiece 200, including the fin-shaped structure 210, using CVD, subatmospheric CVD (SACVD), flowable CVD, spin-on coating, and/or other suitable process. Then the deposited dielectric material is planarized and recessed to form the isolation feature 212. As shown in FIG. 3, the fin-shaped structure rises above the isolation feature 212. The dielectric material for the isolation feature may include silicon oxide, silicon oxynitride, fluorine-doped silicate glass (FSG), a low-k dielectric, combinations thereof, and/or other suitable materials. In the embodiments represented in FIG. 3, the isolation feature 212 completely covers a substantial portion of sidewalls of the base fins patterned from the substrate 202.

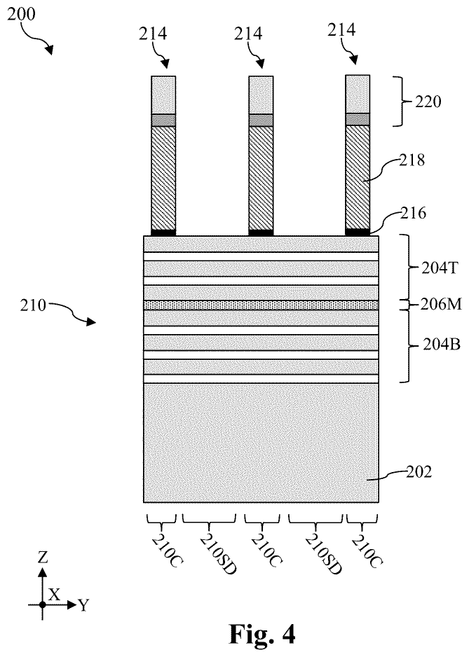

Referring to FIGS. 1 and 4, method 100 includes a block 106 where a dummy gate stack 214 is formed over a channel regions 210C of the fin-shaped structure 210. In some embodiments, a gate replacement process (or gate-last process) is adopted where the dummy gate stack 214 serves as a placeholder for a functional gate structure. Other processes and configuration are possible. To form the dummy gate stack 214, a dummy dielectric layer 216, a dummy gate electrode layer 218, and a gate-top hard mask layer 220 are deposited over the workpiece 200. The deposition of these layers may include use of low-pressure CVD (LPCVD), CVD, plasma-enhanced CVD (PECVD), PVD, ALD, thermal oxidation, e-beam evaporation, or other suitable deposition techniques, or combinations thereof. The dummy dielectric layer 216 may include silicon oxide, the dummy gate electrode layer 218 may include polysilicon, and the gate-top hard mask layer 220 may be a multi-layer that includes silicon oxide and silicon nitride. Using photolithography and etching processes, the gate-top hard mask layer 220 is patterned. The photolithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The etching process may include dry etching (e.g., RIE etching), wet etching, and/or other etching methods. Like the fin-shaped structures 210, the dummy gate stack 214 may also be patterned using double-patterning or multiple-patterning techniques. Thereafter, using the patterned gate-top hard mask 220 as the etch mask, the dummy dielectric layer 216 and the dummy gate electrode layer 218 are then etched to form the dummy gate stack 214. The dummy gate stack 214 extends lengthwise along the X direction to wrap over the fin-shaped structure 210 and lands on the isolation feature 212. The portion of the fin-shaped structure 210 underlying the dummy gate stack 214 defines a channel region 210C. The channel region 210C and the dummy gate stack 214 also define source/drain regions 210SD that are not vertically overlapped by the dummy gate stack 214. The channel region 210C is disposed between two source/drain regions 210SD along the Y direction.

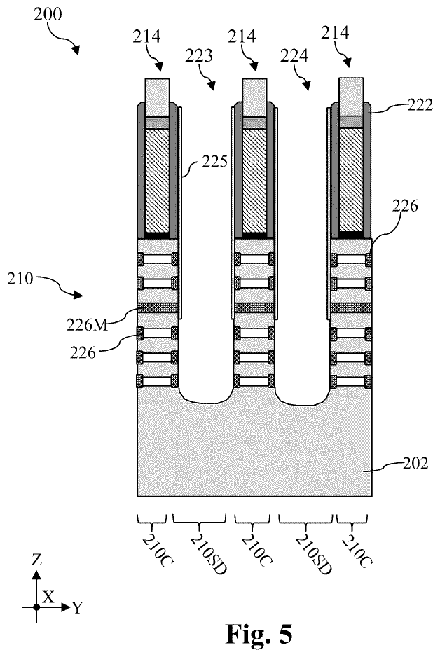

Referring to FIGS. 1 and 5, method 100 includes a block 108 where source/drain regions 210SD of the fin-shaped structure 210 are recessed to form a first source/drain recess 223 and a second source/drain recess 224. Operations at block 108 may include formation of at least one gate spacer layer 222 over the sidewalls of the dummy gate stack 214 before the source/drain regions 210SD are recessed. In some embodiments, the formation of the at least one gate spacer layer 222 includes deposition of one or more dielectric layers over the workpiece 200. In an example process, the one or more dielectric layers are conformally deposited using CVD, SACVD, or ALD. The one or more dielectric layers may include silicon oxide, silicon nitride, silicon carbide, silicon oxynitride, silicon carbonitride, silicon oxycarbide, silicon oxycarbonitride, and/or combinations thereof. After the deposition of the at least one gate spacer layer 222, the workpiece 200 is etched in an anisotropic etch process to form the first source/drain recess 223 and the second source/drain recess 224. The etch process at block 108 may be a dry etch process or a suitable etch process. An example dry etch process may implement an oxygen-containing gas, hydrogen, a fluorine-containing gas (e.g., CF₄, SF₆, NF₃, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As shown in FIG. 5, sidewalls of the sacrificial layers 206 and the channel layers 208 in the channel regions 210C are exposed in the first source/drain recess 223 and the second source/drain recess 224.

Referring to FIGS. 1 and 5, method 100 includes a block 110 where inner spacer features 226 are formed. At block 110, the sacrificial layers 206 exposed in the first source/drain recess 223 and the second source/drain recess 224 are selectively and partially recessed to form inner spacer recesses, while the exposed channel layers 208 are substantially unetched. The middle sacrificial layer 206M, due to its greater germanium content, may be substantially removed during the formation of inner spacer recesses. In an embodiment where the channel layers 208 consist essentially of silicon (Si) and sacrificial layers 206 consist essentially of silicon germanium (SiGe), the selective and partial recess of the sacrificial layers 206 may include a SiGe oxidation process followed by a SiGe oxide removal. In that embodiments, the SiGe oxidation process may include use of ozone (O₃). In some other embodiments, the selective recess may be a selective isotropic etching process (e.g., a selective dry etching process or a selective wet etching process), and the extent at which the sacrificial layers 206 are recessed is controlled by duration of the etching process. The selective dry etching process may include use of one or more fluorine-based etchants, such as fluorine gas or hydrofluorocarbons. The selective wet etching process may include use of hydrogen fluoride (HF) or ammonium hydroxide (NH₄OH). After the formation of the inner spacer recesses, an inner spacer material layer is deposited over the workpiece 200, including in the inner spacer recesses. Additionally, as shown in FIG. 5, the inner spacer material layer may also be deposited in the space left behind by selective removal of the middle sacrificial layer 206M. The inner spacer material layer may include silicon oxide, silicon nitride, silicon oxycarbide, silicon oxycarbonitride, silicon carbonitride, metal nitride, or a suitable dielectric material. The deposited inner spacer material layer is then etched back to remove excess inner spacer material layer over the gate spacer layer and sidewalls of the channel layers 208, thereby forming the inner spacer features 226 and the middle dielectric layer 226M as shown in FIG. 5. In some embodiments, the etch back process at block 110 may be a dry etch process that includes use of an oxygen-containing gas, hydrogen, nitrogen, a fluorine-containing gas (e.g., NF₃, CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas (e.g., CF₃I), other suitable gases and/or plasmas, and/or combinations thereof.

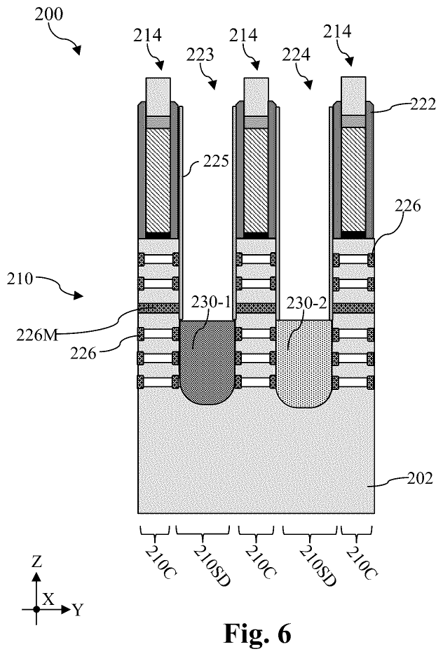

Referring to FIGS. 1 and 6, method 100 includes a block 112 where a first bottom source/drain feature 230-1 and a second bottom source/drain feature 230-2 are formed over the first source/drain recess 223 and the second source/drain recess 224, respectively. For ease of reference, the first bottom source/drain feature 230-1 and the second bottom source/drain feature 230-2 may be collectively referred to as bottom source/drain features 230. Reference is made to FIG. 6. Before the deposition of the bottom source/drain features 230, a blocking layer 225 is deposited over the workpiece 200 to cover sidewalls of the channel layers 208 formed from the top portion 204T of the superlattice structure 204. The blocking layer 225 is formed of a dielectric material, such as silicon oxide or silicon nitride such that it blocks epitaxial formation on sidewalls of the channel layers 208. Without the blocking layer 225, the epitaxial growth from the top channel layers 208 may merge to block satisfactory formation of the bottom source/drain features 230. As shown in FIG. 6, the blocking layer 225 may be deposited using a deposition method that has less hole filing ability. After the deposition, an etch back may remove excess blocking layer 225 or any blocking layer 225 deposited on the exposed surface of the base fin. The blocking layer 225 may be in direct contact with the inner spacer features 226 in the top portion of the fin-shaped structure 210.

Referring to FIG. 6, after the formation of the blocking layer 225, the bottom source/drain features 230 may be formed using an epitaxial process, such as VPE, UHV-CVD, MBE, and/or other suitable processes. The epitaxial growth process may use gaseous and/or liquid precursors, which interact with the composition of the substrate 202 as well as the channel layers 208. The epitaxial growth of bottom source/drain features 230 may take place from both the top surface of the substrate 202 and the exposed sidewalls of the bottom channel layers 208. The blocking layer 225, due to its dielectric composition, blocks formation of the bottom source/drain features 230 on sidewalls of the channel layers 208 formed from the top portion 204T of the superlattice structure 204. As illustrated in FIG. 6, the deposited bottom source/drain features 230 are in physical contact with (or adjoining) the channel layers 208 formed from the bottom portion 204B of the superlattice structure 204. Although the epitaxial growth of bottom source/drain features 230 is less likely to take place on surfaces of the inner spacer features 226, overgrowth of the bottom source/drain features 230 allow the bottom source/drain features 230 to merge over the inner spacer features 226. Depending on the design, the bottom source/drain features 230 may be n-type or p-type. In the depicted embodiments, the first bottom source/drain feature 230-1 is a p-type source/drain feature and may include silicon germanium (SiGe) doped with a p-type dopant, such as boron (B) and the second bottom source/drain feature 230-2 is an n-type source/drain feature and may include silicon (Si) doped with phosphorus (P). In these depicted embodiments, the first bottom source/drain feature 230-1 may include boron doped silicon germanium (SiGe:B) and the second bottom source/drain feature 230-2 may include phosphorus doped silicon (Si:P).

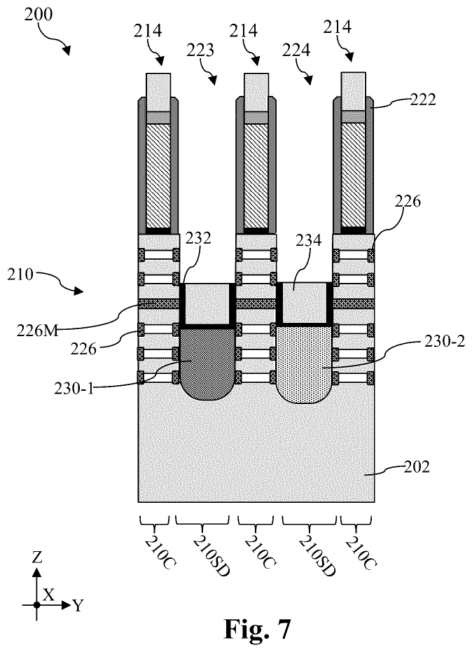

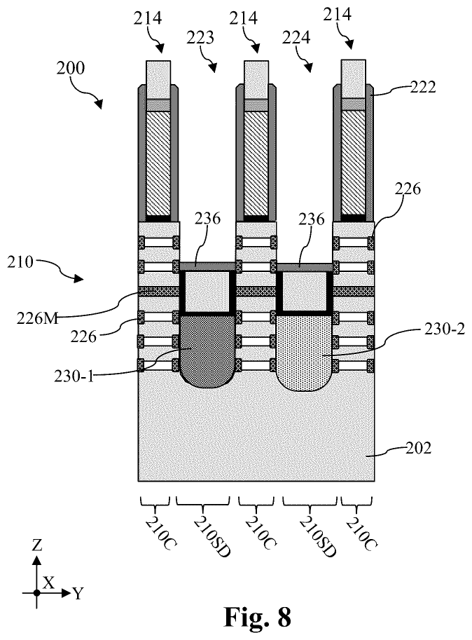

Referring to FIGS. 1 and 7, method 100 includes a block 114 where a bottom contact etch stop layer (CESL) 232 and a bottom interlayer dielectric (ILD) layer 234 are deposited over the first bottom source/drain feature 230-1 and the second bottom source/drain feature 230-2. The bottom CESL 232 may include silicon nitride, silicon oxynitride, and/or other materials known in the art and may be formed by CVD, ALD, plasma-enhanced chemical vapor deposition (PECVD) process and/or other suitable deposition or oxidation processes. In some embodiments, the bottom CESL 232 is first conformally deposited on the workpiece 200 and the bottom ILD layer 234 is deposited over the bottom CESL 232 by spin-on coating, FCVD, CVD, or other suitable deposition technique. The bottom ILD layer 234 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, after formation of the bottom ILD layer 234, the workpiece 200 may be annealed to improve integrity of the bottom ILD layer 234. As shown in FIG. 8, the bottom CESL 232 and the bottom ILD layer 234 are etched back to exposed sidewalls of the top channel layers 208 formed from the top portion 204T of the superlattice structure 204. It is noted that the blocking layer 225 may also be removed during the etch back of the bottom CESL 232 and the bottom ILD layer 234.

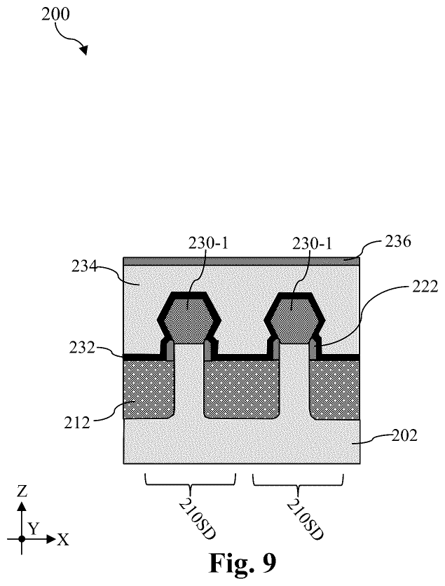

Referring to FIGS. 1, 8 and 9, method 100 includes a block 116 where an etch stop layer (ESL) 236 over the bottom CESL 232 and the bottom ILD layer 234. The ESL 236 may include silicon nitride or silicon oxynitride and is in direct contact with top surfaces of the bottom CESL 232 and the bottom ILD layer 234. The ESL 236 may be deposited using ALD, CVD, or a suitable method. An etch back may be formed using a dry etchant or a wet etchant to expose sidewalls of the top channel layers 208 formed from the top portion 204T of the superlattice structure 204. As shown FIGS. 8 and 9, the bottom CESL 232 conformally covers the top surface of the isolation feature 212, sidewalls of the at least one gate spacer layer 222, and surfaces of the bottom source/drain features 230. The bottom ILD layer 234 is disposed over the bottom CESL 232 to provide a planar top surface. The ESL 236 is deposited on the planar top surface. It is noted that FIG. 8 is a fragmentary cross-sectional view that cuts across the bottom source/drain features 230 along the Y direction while FIG. 9 is a fragmentary cross-sectional view that may cut across two first bottom source/drain features 230-1 along the X direction. As shown in FIG. 8, the ESL 236 may be in direct contact with at least one of the inner spacer features 226.

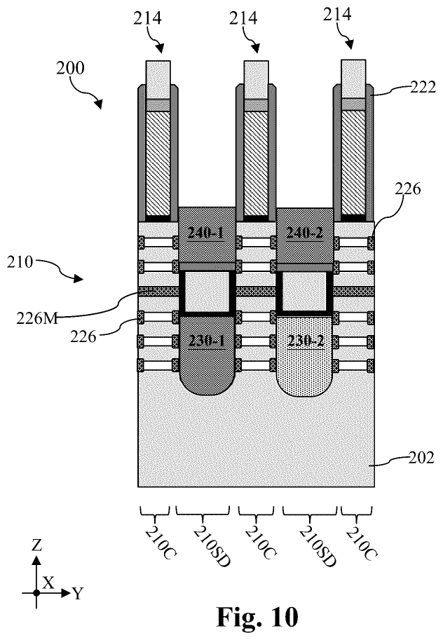

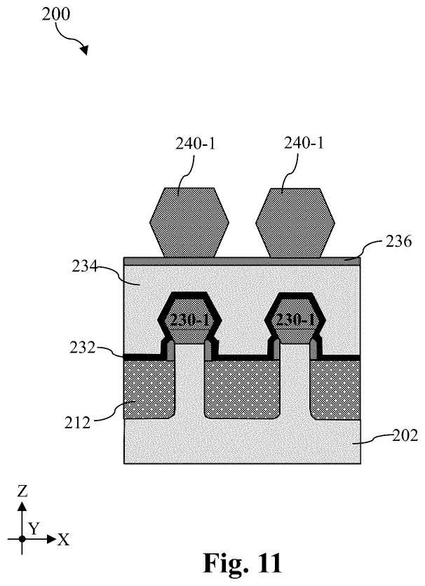

Referring to FIGS. 1, 10 and 11, method 100 includes a block 118 where a first top source/drain feature 240-1 and a second top source/drain feature 240-2 are formed over the ESL 236. For ease of reference, the first top source/drain feature 240-1 and the second top source/drain feature 240-2 may be collectively referred to as top source/drain features 240. The top source/drain features 240 may be formed using an epitaxial process, such as VPE, UHV-CVD, MBE, and/or other suitable processes. The epitaxial growth process may use gaseous and/or liquid precursors, which interact with composition of the top channel layers 208 formed from the top portion 204T of the superlattice structure 204. The epitaxial growth of top source/drain features 240 may take place from the exposed sidewalls of the top channel layers 208. The deposited top source/drain features 240 are in physical contact with (or adjoining) the channel layers 208 formed from the top portion 204T of the superlattice structure 204. It is noted that because the epitaxial growth is less likely to take place on surfaces of the ESL 236, the epitaxial growth environment of the top source/drain features 240 is less favorable than that of the bottom source/drain feature 230, which also grows from surfaces of the substrate 202. It is observed that the lack of the additional semiconductor surface may cause the top source/drain features 240 to have more defects. The additional defects may reduce the stress that the top source/drain features 240 may exert on the top channel layers 208. Depending on the design, the top source/drain features 240 may be n-type or p-type. In the depicted embodiments, the top source/drain features 240 are p-type source/drain features and may include silicon germanium (SiGe) doped with a p-type dopant, such as boron (B). In these depicted embodiments, the top source/drain features 240 may include boron doped silicon germanium (SiGe:B). It is noted that FIG. 10 is a fragmentary cross-sectional view that cuts across the top source/drain features 240 along the Y direction while FIG. 11 is a fragmentary cross-sectional view that may cut across two first top source/drain features 240-1 along the X direction.

To prepare the top source/drain features 240 for the subsequent oxidation and removal process, deposition at block 118 lasts longer to provide thicker top source/drain features 240. As shown in FIG. 11, compared to the bottom source/drain features 230, the top source/drain features 240 are allowed to grow wider along the X direction and taller along the Z direction. In some embodiments, the Z-direction thickness of the top source/drain features 240 is allowed to grow to be about 10%-30% more than the Z-direction thickness of the bottom source/drain features 230. That is, ahead of the oxidation process, a ratio of a thickness of the top source/drain features 240 to a thickness of the bottom source/drain features 230 may be between about 1.1 and about 1.3.

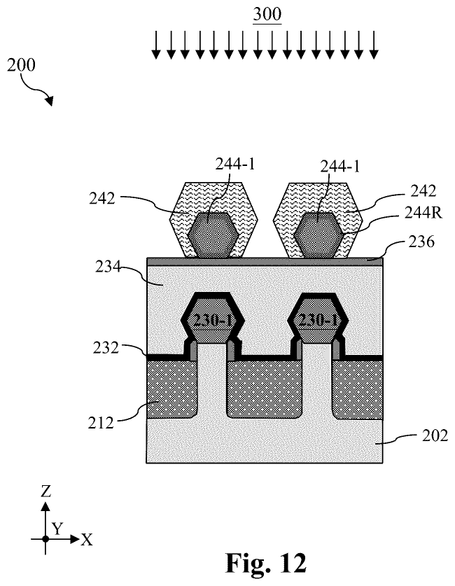

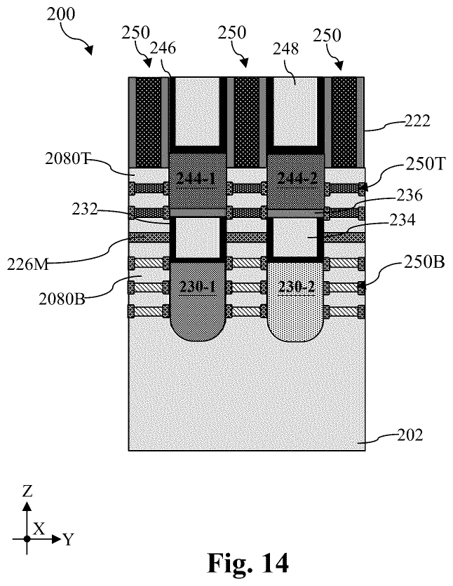

Referring to FIGS. 1 and 12, method 100 includes a block 120 where the first top source/drain feature 240-1 and the second top source/drain feature 240-2 are oxidized in an anneal process 300 to form a surface oxide layer 242. In some embodiments, the anneal process 300 may include flash anneal, cyclic anneal, or spike anneal in presence of an oxygen source such as oxygen or water vapor (i.e., steam). In some instances, the anneal process 300 includes an anneal temperature between about 800° C. and about 1100° C. As shown in FIG. 12, the anneal process 300 oxidizes the top source/drain features 240 to form the surface oxide layer 242. The surface oxide layer 242 includes silicon germanium oxide (SGO). It is observed that the oxidation at block 120 causes condensation of germanium at the interface with the surface oxide layer 242. Such condensation forms a germanium-rich layer 244R, shown in a darker shade in FIG. 12. A thickness of the germanium-rich layer 244R depends on the time of the anneal process 300. In some instances, the thickness of the germanium-rich layer 244R may be between about 10 Å and about 20 Å. In other words, there is a germanium concentration gradient from a surface of the germanium-rich layer 244 inward into the top source/drain feature 240, with a highest local germanium concentration falling in the germanium-rich layer 244R. Due to the lattice mismatch between germanium and silicon, this germanium-rich layer 244R increases the strain in the top source/drain features 240, which in turn exert more stress on the top channel layers 208 formed from the top portion 204T of the superlattice structure 204. Referring to FIG. 12, the germanium-rich layer 244R and the rest of the non-oxidized portion of the top source/drain features 240 will form the stained top source/drain features 244, which includes the first stained top source/drain feature 244-1 and the second strained top source/drain feature 244-2 (shown in FIG. 14). In some embodiments, the top source/drain features 240 may have a germanium content between about 20% and about 50%. The germanium-rich layer 244R may have a germanium content between about 40% and about 100%. When the germanium-rich layer 244R has less than 40% germanium, the strained top source/drain features 244 may not sufficiently strain the channel.

As described above, the top source/drain features 240 may be more defective than the bottom source/drain features 230 because they do not have a large semiconductor surface to assist their epitaxial growth. In some embodiments, the grain boundary mismatch and stacking faults may cause voids or seams as the top source/drain features 240 grow from sidewalls of the channel layers 208. The germanium condensation that takes place at block 120 is shown to help fill such seams or voids. The reduction of seams and voids helps improve the conductivity of the top source/drain features 240.

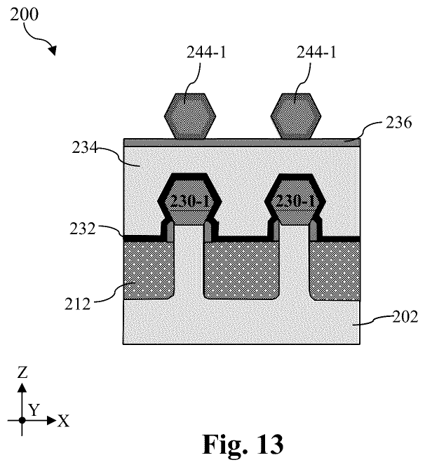

Referring to FIGS. 1 and 13, method 100 includes a block 122 where the surface oxide layer 242 are selectively removed to form a first strained top source/drain feature 244-1 and a second strained top source/drain feature 244-2. In some embodiments, the surface oxide layer 242 may be selectively removed using a selective dry etch or a selective wet etch. In some embodiments, block 122 includes a wet etch and use of ammonium hydroxide (NH₄OH). As shown in FIG. 13, the selective removal of the surface oxide layer 242 leaves behind strained top source/drain features 244, which includes the first strained top source/drain feature 244-1 and the second strained top source/drain feature 244-2 (shown in FIG. 14). After the removal of the surface oxide layer 242, the strained top source/drain features 244 (which include the first strained top source/drain feature 244-1 and the second strained top source/drain feature 244-2) and the bottom source/drain features 230 may have similar dimensions. That is, the surface oxide layer 242 substantially accounts for the additional thickness of the top source/drain features 240. The extra volume is offset after the removal of the surface oxide layer 242.

Referring to FIGS. 1 and 14, method 100 includes a block 124 where a top CESL 246 and a top ILD layer 248 are deposited over the first strained top source/drain feature 244-1 and the second strained top source/drain feature 244-2. The top CESL 246 may include silicon nitride, silicon oxynitride, and/or other materials known in the art and may be formed by CVD, ALD, plasma-enhanced chemical vapor deposition (PECVD) process and/or other suitable deposition or oxidation processes. In some embodiments, the top CESL 246 is first conformally deposited on the workpiece 200 and the ILD layer 248 is deposited over the top CESL 246 by spin-on coating, FCVD, CVD, or other suitable deposition technique. The ILD layer 248 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, after formation of the ILD layer 248, the workpiece 600 may be annealed to improve integrity of the ILD layer 248. To remove excess materials and to expose top surfaces of the dummy gate stacks 214, a planarization process, such a chemical mechanical polishing (CMP) process may be performed.

Referring to FIGS. 1 and 14, method 100 includes a block 126 where the dummy gate stack 214 is replaced with a gate structure. Operations at block 126 may include removal of the dummy gate stacks 214, release of the channel layers 208 as channel members 2080, and formation of gate structures 250 to wrap around the channel members 2080. The removal of the dummy gate stacks 214 may include one or more etching processes that are selective to the material in the dummy gate stacks 214. For example, the removal of the dummy gate stacks 214 may be performed using as a selective wet etch, a selective dry etch, or a combination thereof. After the removal of the dummy gate stacks 214, sidewalls of the channel layers 208 and sacrificial layers 206 in the channel regions 210C are exposed. Thereafter, the sacrificial layers 206 in the channel regions 210C are selectively removed to release the channel layers 208 as the channel members 2080. As shown in FIG. 14, the channel members 2080 includes bottom channel members 2080B below the middle dielectric layer 226M and top channel members 2080T over the middle dielectric layer 226M. Here, because the dimensions of the channel members 2080 are nanoscale, the channel members 2080 may also be referred to as nanostructures. The selective removal of the sacrificial layers 206 may be implemented by selective dry etch, selective wet etch, or other selective etch processes. In some embodiments, the selective wet etching includes an APM etch (e.g., ammonia hydroxide-hydrogen peroxide-water mixture). In some other embodiments, the selective removal includes SiGe oxidation followed by a silicon germanium oxide removal. For example, the oxidation may be provided by ozone clean and then silicon germanium oxide removed by an etchant such as NH₄OH.

With the channel members 2080 released, the gate structure 250 is deposited to wrap around each of the channel members 2080, thereby forming a bottom multi-gate transistor and a top multi-gate transistor disposed over the bottom multi-gate transistor. In the depicted embodiments, both the bottom multi-gate transistor and the top multi-gate transistor are MBC transistors. In some embodiments, the gate structure 250 may be a common gate structure to engage the bottom channel members 2080B and the top channel members 2080T. In some other embodiments depicted in the drawings, the gate structure 250 includes a bottom gate portion 250B to engage bottom channel members 2080B and a top gate portion 250T to engage the top channel members 2080T. The bottom gate portion 250B and the top gate portion 250T have different work function layers. When the gate structure 250 includes a bottom gate portion 250B and a top gate portion 250T, the two gate portions may be electrically isolated from each other. For example, the bottom gate portion 250B may include n-type work function layers and the top gate portion 250T may include p-type work function layers. While not explicitly shown in the figures, the gate structure 250 includes an interfacial layer to interface the channel members 2080, a gate dielectric layer over the interfacial layer, a p-type work function layer, or an n-type work function layer. In some embodiments, the interfacial layer includes silicon oxide and may be formed in a pre-clean process. An example pre-clean process may include use of RCA SC-1 (ammonia, hydrogen peroxide and water) and/or RCA SC-2 (hydrochloric acid, hydrogen peroxide and water). The gate dielectric layer is then deposited over the interfacial layer using ALD, CVD, and/or other suitable methods. The gate dielectric layer is formed of high-K dielectric materials. As used and described herein, high-k dielectric materials include dielectric materials having a high dielectric constant, for example, greater than that of thermal silicon oxide (~3.9). The gate dielectric layer may include hafnium oxide. Alternatively, the gate dielectric layer may include other high-K dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba, Sr)TiO₃ (BST), silicon nitride (SiN), silicon oxynitride (SiON), combinations thereof, or other suitable material.

After the deposition of the gate dielectric layer, n-type work function layer and the p-type work function layer may be sequentially deposited over the channel regions 210C. The p-type work function and the n-type work function layer may include a single layer or alternatively a multi-layer structure, such as various combinations of a metal layer with a selected work function to enhance the device performance (work function metal layer). The gate structure 250 may also include a liner layer, a wetting layer, an adhesion layer, a metal alloy or a metal silicide. By way of example, the p-type work function layer may include titanium nitride (TiN), tantalum nitride (TaN), ruthenium (Ru), molybdenum (Mo), aluminum (Al), tungsten nitride (WN), zirconium silicide (ZrSi₂), molybdenum silicide (MoSi₂), tantalum silicide (TaSi₂), nickel silicide (NiSi₂), other p-type work function material, or combinations thereof. The n-type work function layer may include titanium (Ti), aluminum (Al), silver (Ag), manganese (Mn), zirconium (Zr), titanium aluminum (TiAl), titanium aluminum carbide (TiAlC), tantalum carbide (TaC), tantalum carbonitride (TaCN), tantalum silicide nitride (TaSiN), tantalum aluminum (TaAl), tantalum aluminum carbide (TaAlC), titanium aluminum nitride (TiAlN), other n-type work function material, or combinations thereof. The gate structure 250 may also include a metal fill to reduce contact resistance. In some instance, the metal fill includes tungsten (W). In the depicted embodiment, the top gate portion 250T includes p-type work function layers.

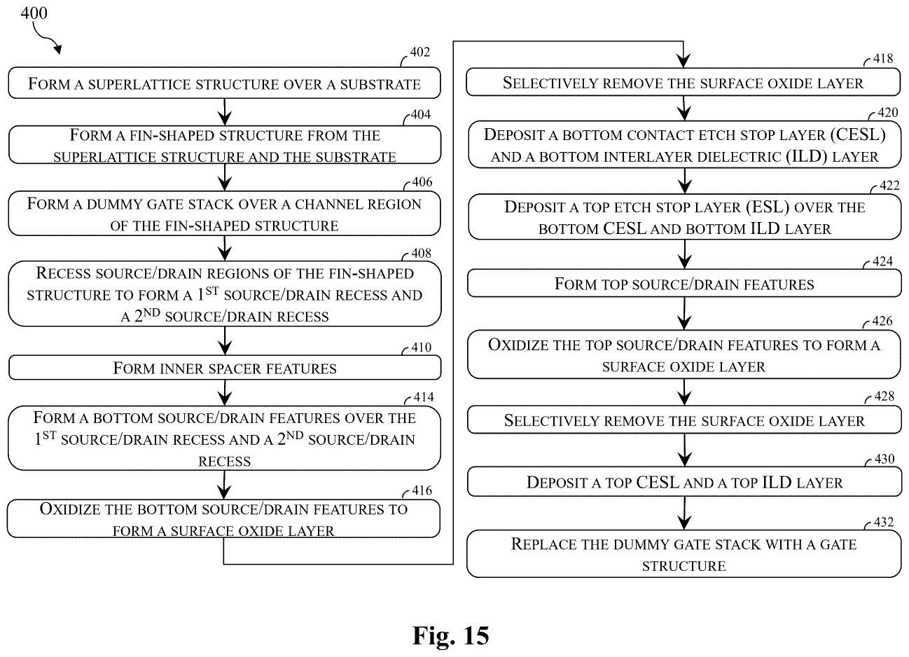

Method 400 illustrated in FIG. 15 forms a C-FET where source/drain features of both the top multi-gate device and bottom multi-gate device are strained using an oxidation process.

Referring to FIGS. 15 and 16, method 400 includes a block 402 where a superlattice structure 204 is formed over a substrate 202. Operations at block 402 are substantially similar to those described above with respect to block 102 of method 100. For that reasons, detailed description of block 402 are omitted for brevity.

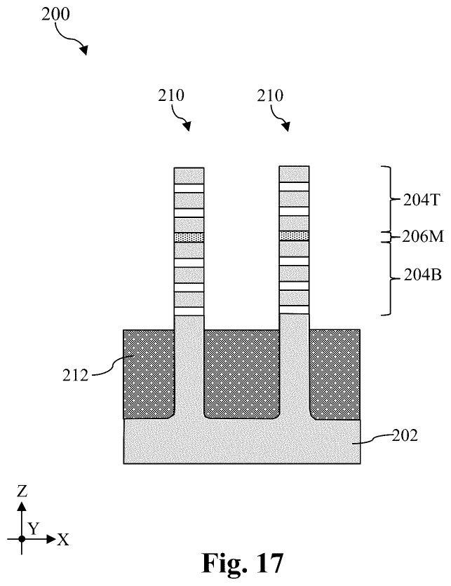

Referring to FIGS. 15 and 17, method 400 includes a block 404 where a fin-shaped structure 210 is formed from the superlattice structure 204 and a portion of the substrate 202. Operations at block 404 are substantially similar to those described above with respect to block 104 of method 100. For that reasons, detailed description of block 404 are omitted for brevity.

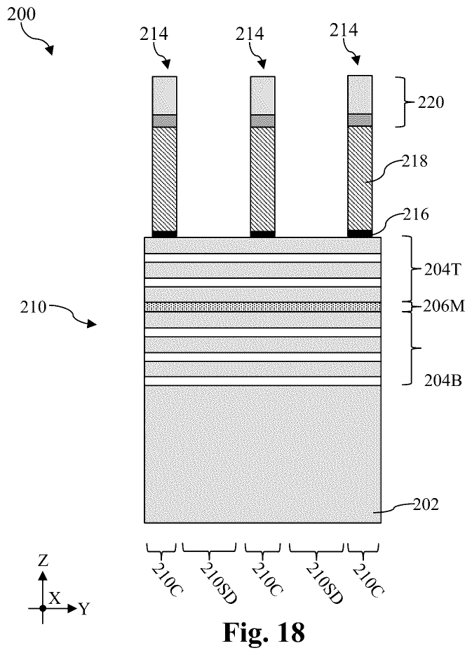

Referring to FIGS. 15 and 18, method 400 includes a block 406 where a dummy gate stack 214 is formed over a channel regions 210C of the fin-shaped structure 210. Operations at block 406 are substantially similar to those described above with respect to block 106 of method 100. For that reasons, detailed description of block 406 are omitted for brevity.

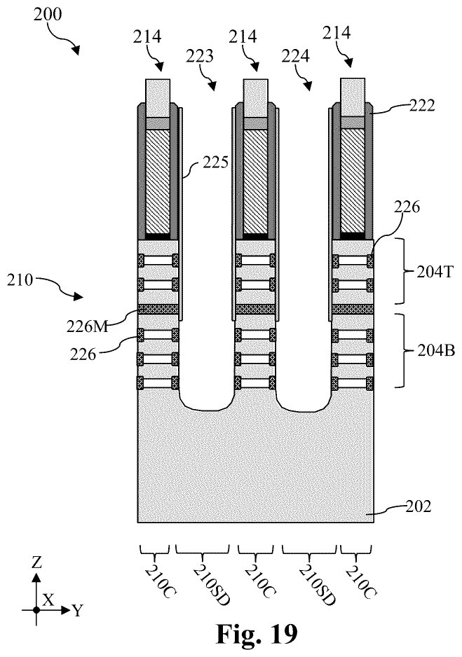

Referring to FIGS. 15 and 19, method 400 includes a block 408 where source/drain regions 210SD of the fin-shaped structure 210 are recessed to form a first source/drain recess 223 and a second source/drain recess 224. Operations at block 408 are substantially similar to those described above with respect to block 108 of method 100. For that reasons, detailed description of block 408 are omitted for brevity.

Referring to FIGS. 15 and 19, method 400 includes a block 410 where inner spacer features 226 are formed. Operations at block 410 are substantially similar to those described above with respect to block 110 of method 100. For that reasons, detailed description of block 410 are omitted for brevity.

Referring to FIGS. 15, 20 and 21, method 400 includes a block 414 where bottom source/drain features 330 are formed over the first source/drain recess 223 and the second source/drain recess 224, respectively. The bottom source/drain features 330 may be formed using an epitaxial process, such as VPE, UHV-CVD, MBE, and/or other suitable processes. The epitaxial growth process may use gaseous and/or liquid precursors, which interact with composition of the bottom channel layers 208 formed from the bottom portion 204B of the superlattice structure 204. The epitaxial growth of bottom source/drain features 330 may take place from the exposed sidewalls of the bottom channel layers 208. The deposited bottom source/drain features 330 are in physical contact with (or adjoining) the channel layers 208 formed from the bottom portion 204B of the superlattice structure 204. Depending on the design, the bottom source/drain features 330 may be n-type or p-type. In the depicted embodiments, the bottom source/drain features 330 are a p-type source/drain features and may include silicon germanium (SiGe) doped with a p-type dopant, such as boron (B). In these depicted embodiments, the bottom source/drain features 330 may include boron doped silicon germanium (SiGe:B). While bottom source/drain features 330 are deposited on exposed surfaces of the substrate 202, various designs may require additional strain in the channel region 210C.

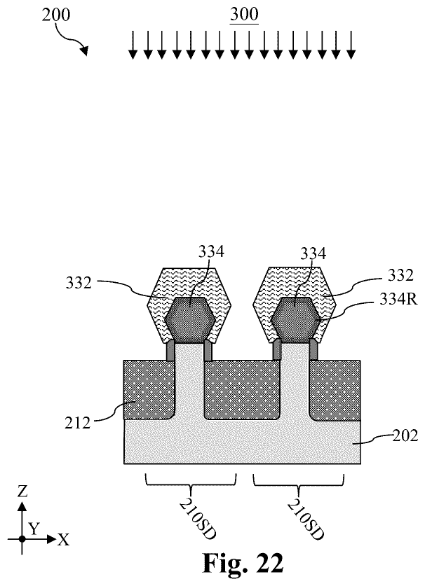

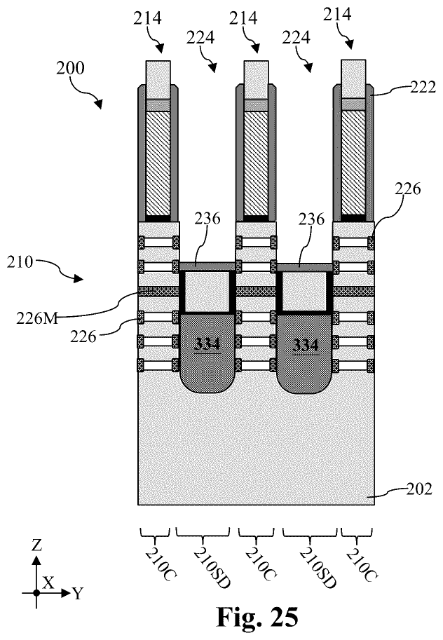

Referring to FIGS. 15 and 22, method 400 includes a block 416 where the bottom source/drain features 330 are oxidized using an anneal process 300 to form a surface oxide layer 332. In some embodiments, the anneal process 300 may include flash anneal, cyclic anneal, or spike anneal in presence of an oxygen source such as oxygen or water vapor (i.e., steam). In some instances, the anneal process 300 includes an anneal temperature between about 800° C. and about 1100° C. As shown in FIG. 22, the anneal process 300 oxidizes the bottom source/drain features 330 to form the surface oxide layer 332. The surface oxide layer 332 includes silicon germanium oxide (SGO). It is observed that the oxidation at block 416 causes condensation of germanium at the interface with the surface oxide layer 332. Such condensation forms a germanium-rich layer 334R, shown in a darker shade in FIG. 25. A thickness of the germanium-rich layer 334R depends on the time of the anneal process 300. In some instances, the thickness of the germanium-rich layer 334R may be between about 10 Å and about 20 Å. Due to the lattice mismatch between germanium and silicon, this germanium-rich layer 334R increases the strain in the bottom source/drain features 330, which in turn exert more stress on the bottom channel layers 208 formed from the bottom portion 204B of the superlattice structure 204. Referring to FIG. 22, the germanium-rich layer 334R and the rest of the non-oxidized portion of the bottom source/drain features 330 will form the stained bottom source/drain features 334. In some embodiments, the bottom source/drain features 330 may have a germanium content between about 20% and about 50%. The germanium-rich layer 334R may have a germanium content between about 40% and about 100%. When the germanium-rich layer 334R has less than 40% germanium, the strained bottom source/drain features 334 may not sufficiently strain the channel.

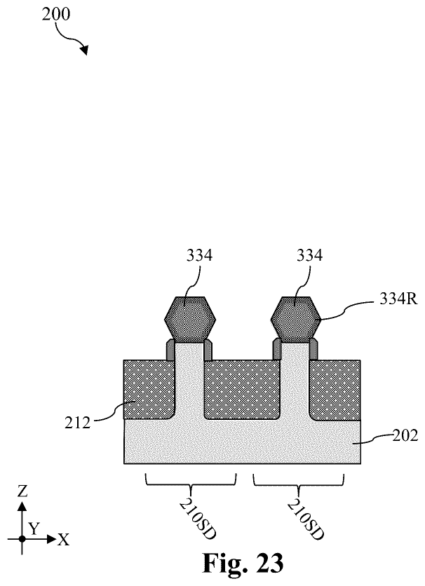

Referring to FIGS. 15 and 23, method 400 includes a block 418 where the surface oxide layer 332 are selectively removed to form strained bottom source/drain features 334. In some embodiments, the surface oxide layer 332 may be selectively removed using a selective dry etch or a selective wet etch. In some embodiments, block 418 includes a wet etch and use of ammonium hydroxide (NH₄OH). As shown in FIG. 23, the selective removal of the surface oxide layer 332 leaves behind strained bottom source/drain features 334.

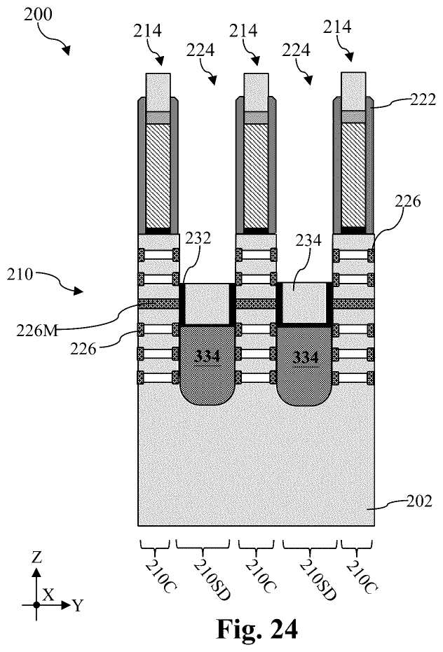

Referring to FIGS. 15 and 24, method 400 includes a block 420 where a bottom contact etch stop layer (CESL) 232 and a bottom interlayer dielectric (ILD) layer 234 are deposited over the strained bottom source/drain features 334. Operations at block 420 are substantially similar to those described above with respect to block 114 of method 100. For that reasons, detailed description of block 420 are omitted for brevity.

Referring to FIGS. 15, 25 and 26, method 400 includes a block 422 where an etch stop layer (ESL) 236 over the bottom CESL 232 and the bottom ILD layer 234. Operations at block 422 are substantially similar to those described above with respect to block 116 of method 100. For that reasons, detailed description of block 422 are omitted for brevity.

Referring to FIGS. 15, 27 and 28, method 400 includes a block 424 where a first top source/drain feature 240-1 and a second top source/drain feature 240-2 are formed over the ESL 236. Operations at block 424 are substantially similar to those described above with respect to block 118 of method 100. For that reasons, detailed description of block 424 are omitted for brevity.

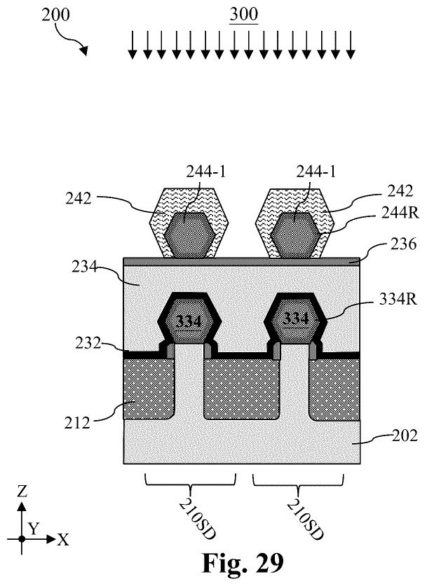

Referring to FIGS. 15 and 29, method 400 includes a block 426 where the first top source/drain feature 240-1 and the second top source/drain feature 240-2 are oxidized to form a surface oxide layer 242. Operations at block 426 are substantially similar to those described above with respect to block 120 of method 100. For that reasons, detailed description of block 426 are omitted for brevity.

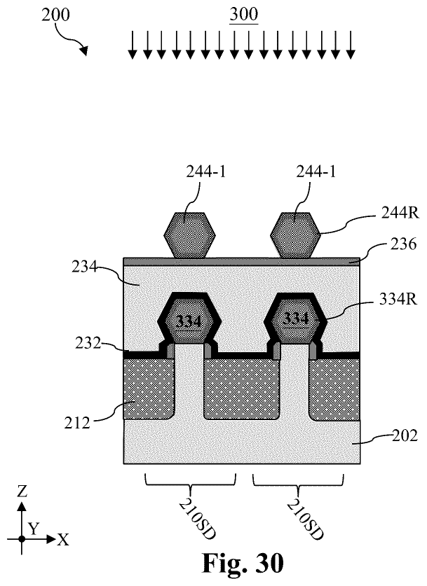

Referring to FIGS. 15 and 30, method 100 includes a block 428 where the surface oxide layer 242 are selectively removed to form a first strained top source/drain feature 244-1 and a second strained top source/drain feature 244-2. Operations at block 428 are substantially similar to those described above with respect to block 122 of method 100. For that reasons, detailed description of block 428 are omitted for brevity.

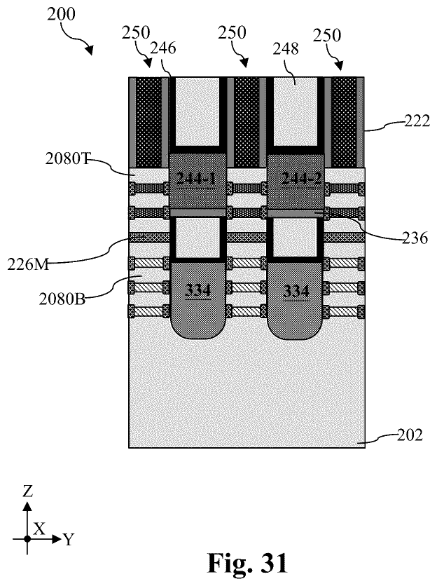

Referring to FIGS. 15 and 31, method 400 includes a block 430 where a top CESL 246 and a top ILD layer 248 are deposited over the first strained top source/drain feature 244-1 and the second strained top source/drain feature 244-2. Operations at block 430 are substantially similar to those described above with respect to block 124 of method 100. For that reasons, detailed description of block 430 are omitted for brevity.

Referring to FIGS. 15 and 31, method 400 includes a block 432 where the dummy gate stack 214 is replaced with a gate structure. Operations at block 432 are substantially similar to those described above with respect to block 126 of method 100. For that reasons, detailed description of block 432 are omitted for brevity.

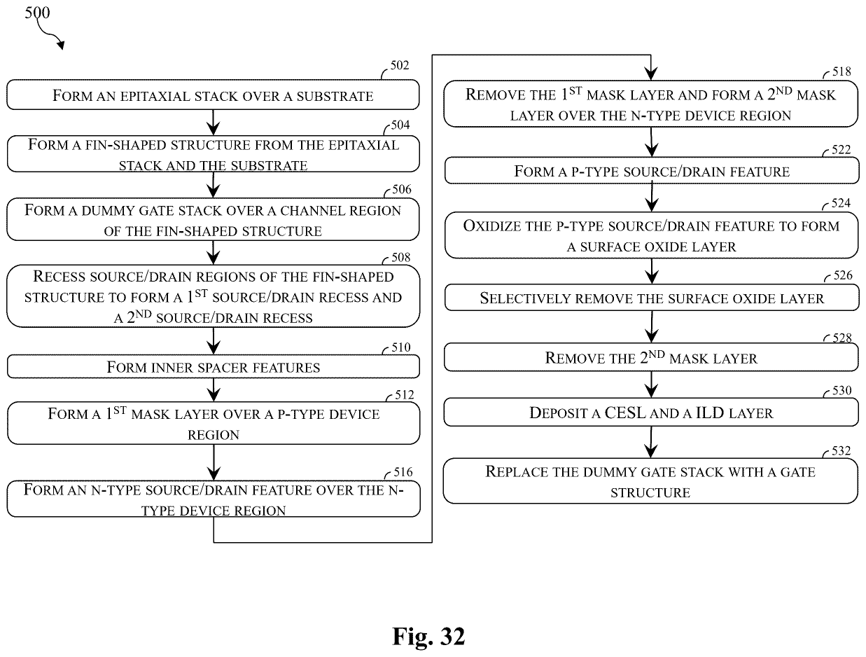

Method 500 illustrated in FIG. 32 forms a multi-gate device where p-type source/drain features are selectively strained using the oxidation process.

Referring to FIGS. 32 and 33, method 500 includes a block 502 where a stack 205 is formed over a substrate 202. Compared to operations at block 102 of method 100 and block 402 of method 400, block 502 forms over the substrate 202 a stack 205, rather than a superlattice structure 204. Detailed description of the substrate 202 is omitted for brevity. The stack 205 has less semiconductor layers than the superlattice structure 204. In the depicted embodiments, the stack 205 includes a plurality of channel layers 208 interleaved by a plurality of sacrificial layers 206. The channel layers 208 and the sacrificial layers 206 may have different semiconductor compositions. In some implementations, the channel layers 208 are formed of silicon (Si) and sacrificial layers 206 are formed of silicon germanium (SiGe). In these implementations, the additional germanium content in the sacrificial layers 206 allow selective removal or recess of the sacrificial layers 206 without substantial damages to the channel layers 208. The sacrificial layers 206 and the channel layers 208 are deposited alternatingly, one-after-another, to form the stack 205. The stack 205 does not include any counterpart for the middle sacrificial layer 206M.

It is noted that the stack 205 in FIG. 33 includes three (3) layers of the channel layers 208 interleaved by three (3) layers of sacrificial layers 206, which is for illustrative purposes only and not intended to be limiting beyond what is specifically recited in the claims. It can be appreciated that any number of the channel layers 208 can be included in the stack 205. The number of layers depends on the desired number of channels members for the multi-gate transistor. In some embodiments, the number of the channel layers 208 in the stack 205 may be between 2 and 5. The thicknesses of the channel layers 208 and the sacrificial layers 206 may be selected based on device performance considerations of the multi-gate transistor as a whole.

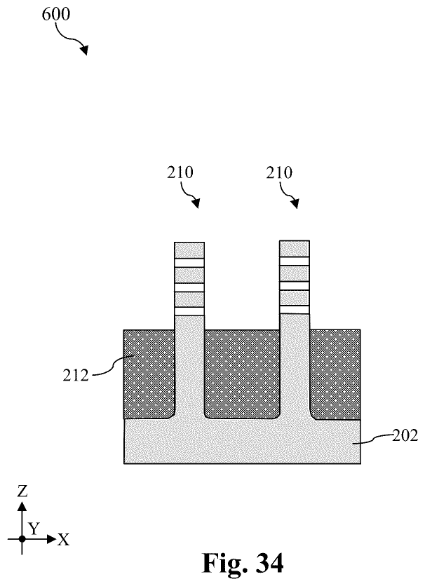

Referring to FIGS. 32 and 34, method 500 includes a block 504 where a fin-shaped structure 210 is formed from the superlattice structure 204 and a portion of the substrate 202. Operations at block 504 are substantially similar to those described above with respect to block 104 of method 100. For that reasons, detailed description of block 504 are omitted for brevity.

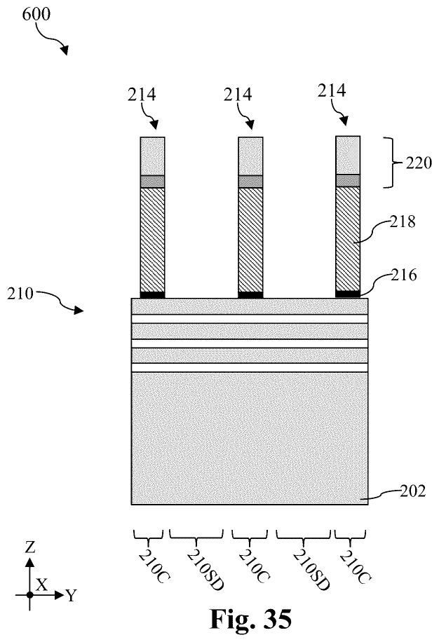

Referring to FIGS. 32 and 35, method 500 includes a block 506 where a dummy gate stack 214 is formed over a channel regions 210C of the fin-shaped structure 210. Operations at block 506 are substantially similar to those described above with respect to block 106 of method 100. For that reasons, detailed description of block 506 are omitted for brevity.

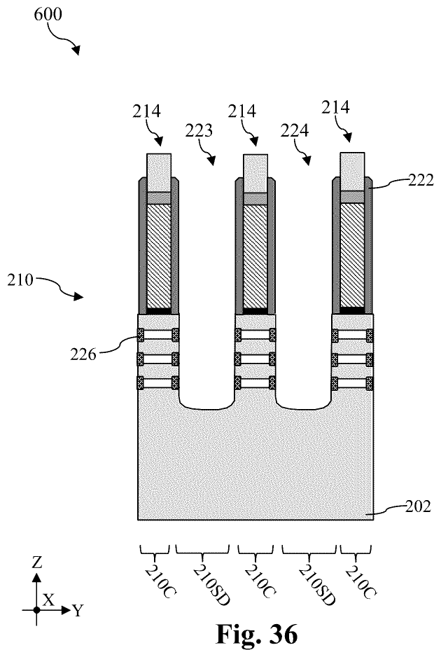

Referring to FIGS. 32 and 36, method 500 includes a block 508 where source/drain regions 210SD of the fin-shaped structure 210 are recessed to form a first source/drain recess 223 and a second source/drain recess 224. Operations at block 508 are substantially similar to those described above with respect to block 108 of method 100. For that reasons, detailed description of block 508 are omitted for brevity.

Referring to FIGS. 32 and 36, method 500 includes a block 510 where inner spacer features 226 are formed. Operations at block 510 are substantially similar to those described above with respect to block 110 of method 100. For that reasons, detailed description of block 510 are omitted for brevity.

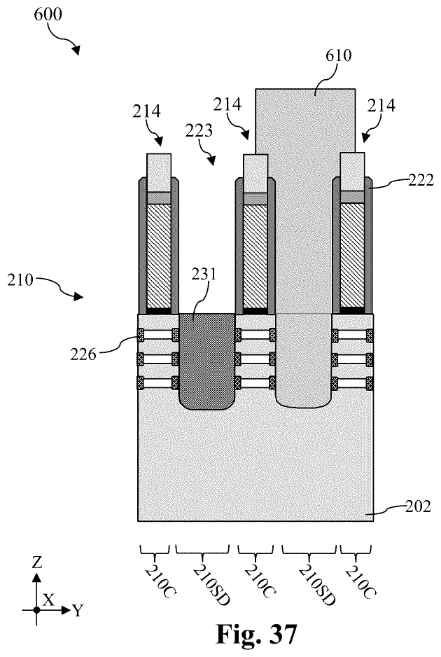

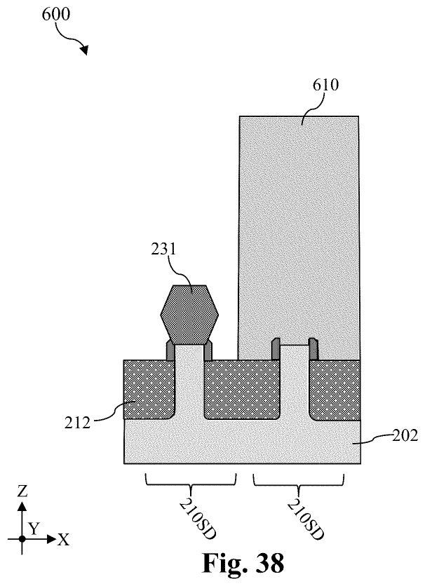

Referring to FIGS. 32, 37 and 38, method 500 includes a block 512 where a first mask layer 610 is formed over a p-type device region. At block 512, the first masking layer 610 is deposited over the workpiece 600 and is then patterned to cover the second source/drain recess 224 while the first source/drain recess 223 is exposed. In one embodiment, the first masking layer 610 is a bottom antireflective coating (BARC) layer that may include polysulfones, polyureas, polyurea sulfones, polyacrylates, poly(vinyl pyridine), or a silicon-containing polymer. Photolithography and etching processes may be used to pattern the first masking layer 610 shown in FIGS. 37 and 38. The photolithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The resulting patterned photoresist layer is then applied as an etch mask to pattern the first masking layer 610. In the depicted embodiments, the second source/drain recess 224 is in the p-type device region and the first source/drain recess 223 is in the n-type device region.

Referring to FIGS. 32, 37 and 38, method 500 includes a block 516 where an n-type source/drain feature 231 is formed over the n-type device region. As shown in FIGS. 37 and 38, the n-type source/drain feature 231 is deposited over the first source/drain recess 223. The n-type source/drain feature 231 may be formed using an epitaxial process, such as VPE, UHV-CVD, MBE, and/or other suitable processes. The epitaxial growth process may use gaseous and/or liquid precursors, which interact with the channel layers 208 in the channel region 210C and the exposed surface of the substrate 202. As shown in FIG. 37, overgrowth of the n-type source/drain feature 231 may merge over the inner spacer features 226. The n-type source/drain feature 231 is an n-type source/drain feature and may include silicon (Si) doped with an n-type dopant, such as phosphorus (P) or arsenic (As). In these depicted embodiments, the n-type source/drain feature 231 may include phosphorus doped silicon (Si:P).

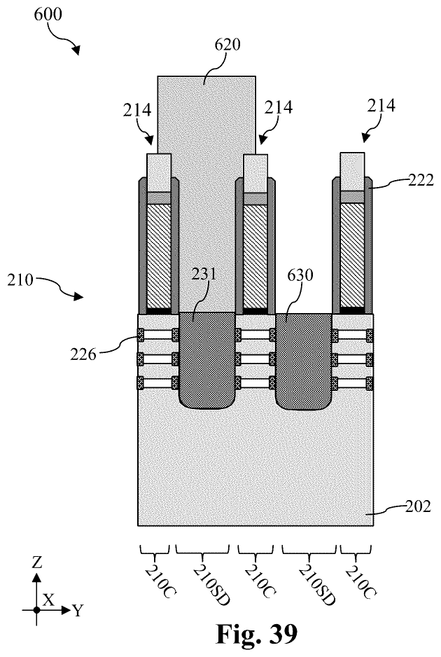

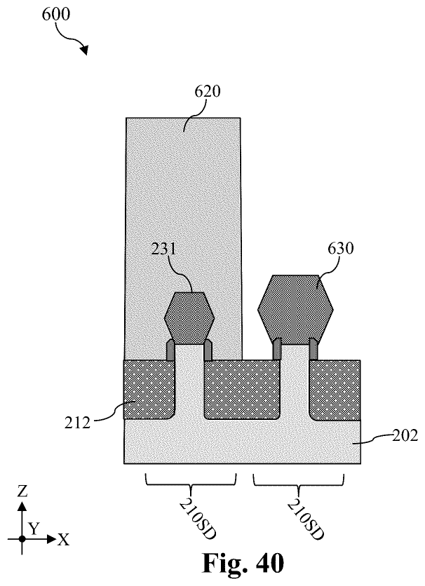

Referring to FIGS. 32, 39 and 40, method 500 includes a block 518 where the first mask layer 610 is removed and a second mask layer 620 is formed over the n-type device region. After the formation of the n-type source/drain feature 231, the first masking layer 610 is removed by, for example, ashing, stripping, or selective etching. At block 518, the second masking layer 620 is deposited over the workpiece 600 and is then patterned to cover the n-type source/drain feature 231 while the second source/drain recess 224 is exposed. In one embodiment, the second masking layer 620 is a bottom antireflective coating (BARC) layer that may include polysulfones, polyureas, polyurea sulfones, polyacrylates, poly(vinyl pyridine), or a silicon-containing polymer. Photolithography and etching processes may be used to pattern the second masking layer 620 shown in FIGS. 39 and 40. The photolithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The resulting patterned photoresist layer is then applied as an etch mask to pattern the second masking layer 620.

Referring to FIGS. 32, 39 and 40, method 500 includes a block 522 where a p-type source/drain feature 630 is formed over the p-type device region. With the second masking layer 620 covering the n-type source/drain feature 231, the p-type source/drain feature 630 is deposited in the second source/drain recess 224. The p-type source/drain feature 630 may be formed using an epitaxial process, such as VPE, UHV-CVD, MBE, and/or other suitable processes. The epitaxial growth process may use gaseous and/or liquid precursors, which interact with the channel layers 208 exposed in the second source/drain recess 224. Therefore, the epitaxial growth of the p-type source/drain feature 630 may take place from the exposed sidewalls of the channel layers 208 and the exposed surfaces of the substrate 202, but not from surfaces of the inner spacer features 226. As shown in FIG. 39, overgrowth of the p-type source/drain feature 630 may merge over the inner spacer features 226. In these depicted embodiments, the p-type source/drain feature 630 includes silicon germanium doped with boron (SiGe: B). After the formation of the p-type source/drain feature 630, the second masking layer 620 still covers the n-type source/drain feature 231.

To prepare the p-type source/drain feature 630 for the subsequent oxidation and removal process, deposition at block 524 lasts longer to provide thicker p-type source/drain feature 630. As shown in FIG. 45, compared to the n-type source/drain features 231, the p-type source/drain feature 630 is allowed to grow wider along the X direction and taller along the Z direction. In some embodiments, the Z-direction thickness of the p-type source/drain features 630 is allowed to grow to be about 10%-30% more than the Z-direction thickness of the n-type source/drain feature 231. That is, ahead of the oxidation process, a ratio of a thickness of the p-type source/drain feature 630 to a thickness of the n-type source/drain feature 231 may be between about 1.1 and about 1.3.

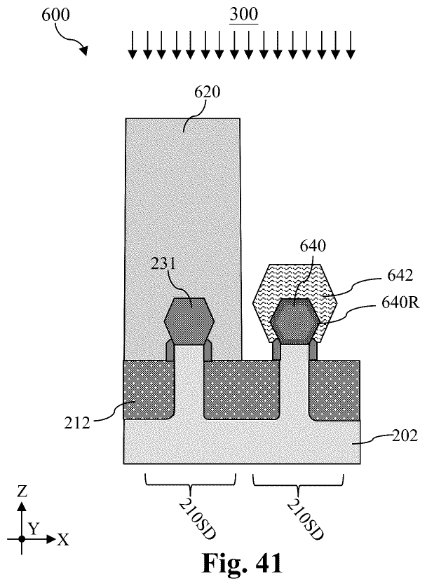

Referring to FIGS. 32 and 41, method 500 includes a block 524 where the p-type source/drain feature 630 is oxidized to form a surface oxide layer 642. In some embodiments, the anneal process 300 may include flash anneal, cyclic anneal, or spike anneal in presence of an oxygen source such as oxygen or water vapor (i.e., steam). In some instances, the anneal process 300 includes an anneal temperature between about 800° C. and about 1100° C. As shown in FIG. 41, the anneal process 300 oxidizes the p-type source/drain feature 630 to form the surface oxide layer 642. The surface oxide layer 642 includes silicon germanium oxide (SGO). It is observed that the oxidation at block 526 causes condensation of germanium at the interface with the surface oxide layer 642. Such condensation forms a germanium-rich layer 640R, shown in a darker shade in FIG. 41. A thickness of the germanium-rich layer 640R depends on the time of the anneal process 300. In some instances, the thickness of the germanium-rich layer 640R may be between about 10 Å and about 20 Å. to the lattice mismatch between germanium and silicon, this germanium-rich layer 640R increases the strain in the p-type source/drain features 630, which in turn exert more stress on the top channel layers 208 in the p-type device region. Referring to FIG. 4, the germanium-rich layer 640R and the rest of the non-oxidized portion of the p-type source/drain features 630 will form the stained p-type source/drain features 640. In some embodiments, the p-type source/drain feature 630 may have a germanium content between about 20% and about 50%. The germanium-rich layer 640R may have a germanium content between about 40% and about 100%. When the germanium-rich layer 640R has less than 40% germanium, the strained p-type source/drain features 640 may not sufficiently strain the channel.

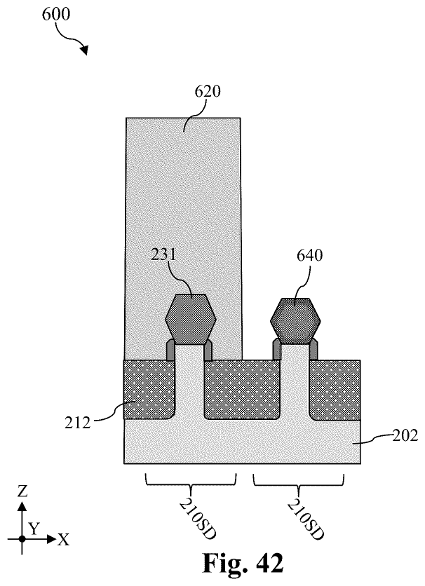

Referring to FIGS. 32 and 42, method 500 includes a block 526 where the surface oxide layer 642 are selectively removed to form a strained p-type source/drain feature 640. In some embodiments, the surface oxide layer 642 may be selectively removed using a selective dry etch or a selective wet etch. In some embodiments, block 528 includes a wet etch and use of ammonium hydroxide (NH₄OH). As shown in FIG. 42, the selective removal of the surface oxide layer 242 leaves behind strained p-type source/drain feature 640. After the removal of the surface oxide layer 642, the strained p-type source/drain feature 640 and the n-type source/drain feature 231 may have similar dimensions. That is, the surface oxide layer 642 substantially accounts for the additional thickness of the p-type source/drain features 630. The extra volume is offset after the removal of the surface oxide layer 642.

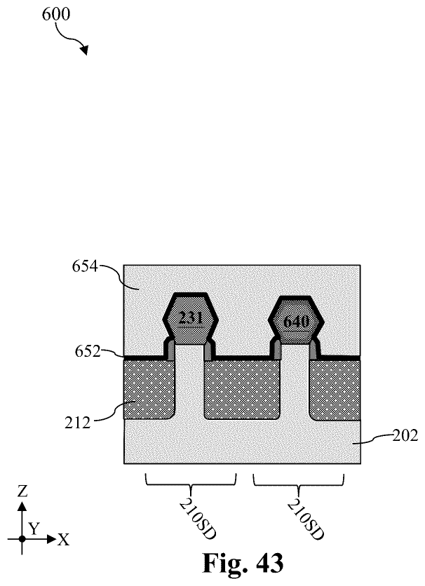

Referring to FIGS. 32 and 43, method 500 includes a block 528 where the second mask layer 620 is removed. After the removal of the surface oxide layer 642, the second masking layer 620 is selectively removed by ashing, stripping, or selective etching.

Referring to FIGS. 32 and 43, method 500 includes a block 530 where a CESL 652 and an ILD layer 654 are deposited over the strained p-type source/drain feature 640. The CESL 652 may include silicon nitride, silicon oxynitride, and/or other materials known in the art and may be formed by CVD, ALD, plasma-enhanced chemical vapor deposition (PECVD) process and/or other suitable deposition or oxidation processes. In some embodiments, the CESL 652 is first conformally deposited on the workpiece 600 (including the n-type source/drain feature 231 and the strained p-type source/drain feature 640) and the ILD layer 654 is deposited over the top CESL 652 by spin-on coating, FCVD, CVD, or other suitable deposition technique. The ILD layer 654 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, after formation of the ILD layer 654, the workpiece 600 may be annealed to improve integrity of the ILD layer 654. To remove excess materials and to expose top surfaces of the dummy gate stacks 214, a planarization process, such a chemical mechanical polishing (CMP) process may be performed.

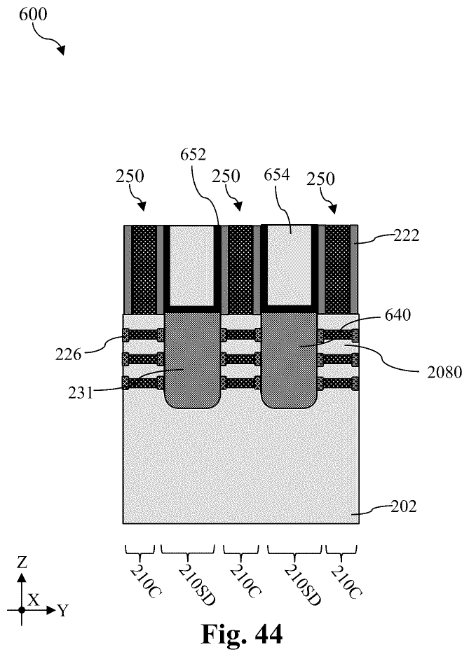

Referring to FIGS. 32 and 44, method 500 includes a block 532 where the dummy gate stack 214 is replaced with a gate structure 250. Operations at block 532 may include removal of the dummy gate stacks 214, release of the channel layers 208 as channel members 2080, and formation of gate structures 250 to wrap around the channel members 2080. The removal of the dummy gate stacks 214 may include one or more etching processes that are selective to the material in the dummy gate stacks 214. For example, the removal of the dummy gate stacks 214 may be performed using as a selective wet etch, a selective dry etch, or a combination thereof. After the removal of the dummy gate stacks 214, sidewalls of the channel layers 208 and sacrificial layers 206 in the channel regions 210C are exposed. Thereafter, the sacrificial layers 206 in the channel regions 210C are selectively removed to release the channel layers 208 as the channel members 2080. Here, because the dimensions of the channel members 2080 are nanoscale, the channel members 2080 may also be referred to as nanostructures. The selective removal of the sacrificial layers 206 may be implemented by selective dry etch, selective wet etch, or other selective etch processes. In some embodiments, the selective wet etching includes an APM etch (e.g., ammonia hydroxide-hydrogen peroxide-water mixture). In some other embodiments, the selective removal includes SiGe oxidation followed by a silicon germanium oxide removal. For example, the oxidation may be provided by ozone clean and then silicon germanium oxide removed by an etchant such as NH₄OH.

With the channel members 2080 released, the gate structure 250 is deposited to wrap around each of the channel members 2080, thereby a multi-gate transistor. In the depicted embodiments, the multi-gate transistor is an MBC transistor. In some embodiments, the gate structure 250 shown in FIG. 44 includes an interfacial layer to interface the channel members 2080, a gate dielectric layer over the interfacial layer, and at least one work function layer. In some embodiments, the interfacial layer includes silicon oxide and may be formed in a pre-clean process. An example pre-clean process may include use of RCA SC-1 (ammonia, hydrogen peroxide and water) and/or RCA SC-2 (hydrochloric acid, hydrogen peroxide and water). The gate dielectric layer is then deposited over the interfacial layer using ALD, CVD, and/or other suitable methods. The gate dielectric layer is formed of high-K dielectric materials. As used and described herein, high-k dielectric materials include dielectric materials having a high dielectric constant, for example, greater than that of thermal silicon oxide (~3.9). The gate dielectric layer may include hafnium oxide. Alternatively, the gate dielectric layer may include other high-K dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba, Sr)TiO₃ (BST), silicon nitride (SiN), silicon oxynitride (SiON), combinations thereof, or other suitable material.

After the deposition of the gate dielectric layer, at least one work function layer may be sequentially deposited over the channel regions 210C. The at least one work function layer may include a p-type work function layer, an n-type work function layer, or a combination thereof. The gate structure 250 may also include a liner layer, a wetting layer, an adhesion layer, a metal alloy or a metal silicide. Example p-type work function layers may include titanium nitride (TiN), tantalum nitride (TaN), ruthenium (Ru), molybdenum (Mo), aluminum (Al), tungsten nitride (WN), zirconium silicide (ZrSi₂), molybdenum silicide (MoSi₂), tantalum silicide (TaSi₂), nickel silicide (NiSi₂), other p-type work function material, or combinations thereof. Example n-type work function layer may include titanium (Ti), aluminum (Al), silver (Ag), manganese (Mn), zirconium (Zr), titanium aluminum (TiAl), titanium aluminum carbide (TiAlC), tantalum carbide (TaC), tantalum carbonitride (TaCN), tantalum silicide nitride (TaSiN), tantalum aluminum (TaAl), tantalum aluminum carbide (TaAlC), titanium aluminum nitride (TiAlN), other n-type work function material, or combinations thereof. The gate structure 250 may also include a metal fill to reduce contact resistance. In some instance, the metal fill includes tungsten (W).

In one exemplary aspect, the present disclosure is directed to a semiconductor device. The semiconductor device includes a substrate, a first lower source/drain feature and a second lower source/drain feature disposed over the substrate, a first plurality of nanostructures extending between the first lower source/drain feature and the second lower source/drain feature, a first gate structure wrapping around each of the first plurality of nanostructures, a first contact etch stop layer (CESL) and a first dielectric layer over the first lower source/drain feature, a first etch stop layer (ESL) over and in contact with the first CESL and the first dielectric layer, a second CESL) and a second dielectric layer over the second lower source/drain feature, a second ESL over and in contact with the second CESL and the second dielectric layer, a first upper source/drain feature over the first ESL, a second upper source/drain feature over the second ESL, a second plurality of nanostructures extending between the first upper source/drain feature and the second upper source/drain feature, and a second gate structure wrapping around each of the second plurality of nanostructures.

In some embodiments, the first CESL and the second CESL include silicon nitride or silicon oxynitride. In some implementations, the first ESL and the second ESL include silicon nitride and the first dielectric layer and the second dielectric layer include silicon oxide. In some implementations, the first gate structure and the second gate structure are vertically spaced apart from one another by a middle dielectric layer. In some embodiments, a sidewall of the middle dielectric layer is in contact with the first CESL. In some instances, the first upper source/drain feature and the second upper source/drain feature include silicon germanium and a p-type dopant. Each of the first upper source/drain feature and the second upper source/drain feature includes a concentration gradient of germanium with a greatest germanium concentration adjacent surfaces of the first upper source/drain feature and the second upper source/drain feature. In some embodiments, the p-type dopant includes boron (B). In some embodiments, the first lower source/drain feature includes silicon germanium and a p-type dopant and the second lower source/drain feature include silicon and an n-type dopant. In some instances, the first plurality of nanostructures are interleaved by a first plurality of inner spacer features, the second plurality of nanostructures are interleaved by a second plurality of inner spacer features, the first CESL is in contact with at least one of the first plurality of inner spacer features, and the first ESL is in contact with at least one of the second plurality of inner spacer features.

In another exemplary aspect, the present disclosure is directed to a semiconductor structure. The semiconductor structure includes a substrate, a first source/drain feature disposed on the substrate, a first contact etch stop layer (CESL) disposed on the first source/drain feature, a first dielectric layer disposed over the first CESL and spaced apart from the first source/drain feature, an etch stop layer (ESL) disposed on and in contact with the first CESL and the first dielectric layer, a second source/drain feature disposed over the ESL, a second (CESL) disposed on the second source/drain feature, and a second dielectric layer disposed over the second CESL and spaced apart from the second source/drain feature. The first source/drain feature includes silicon and an n-type dopant and the second source/drain feature includes silicon germanium and a p-type dopant.

In some embodiments, the first CESL and the second CESL include silicon nitride or silicon oxynitride, the ESL include silicon nitride and the first dielectric layer and the second dielectric layer include silicon oxide. In some implementations, the ESL is in contact with top surfaces of the first CESL and the first dielectric layer. In some instances, first source/drain feature partially extends into the substrate. In some embodiments, the second source/drain feature includes a surface germanium-rich layer and a germanium content of the surface germanium-rich layer is greater than a germanium content of a rest of the second source/drain feature. In some instances, the germanium content of the surface germanium-rich layer is between about 40% and about 100%.

In yet another exemplary aspect, the present disclosure is directed to a method. The method includes receiving a workpiece that includes a silicon substrate, a first stack over the silicon substrate, the first stack including a first plurality of channel layers interleaved by a first plurality of sacrificial layers, a middle silicon germanium layer over the first stack, and a second stack over the middle silicon germanium layer, the second stack including a second plurality of channel layers interleaved by a second plurality of sacrificial layers, patterning the silicon substrate, the first stack and the second stack to form a fin-shaped structure having a first channel region, a second channel region, and a source/drain region between the first channel region and the second channel region, forming an isolation feature around the fin-shaped structure, forming a first dummy gate stack over the first channel region and a second dummy gate stack over the second channel region, after the forming the first dummy gate stack and the second dummy gate stack, recessing the source/drain region into the silicon substrate to form a source/drain recess, forming an n-type source/drain feature over the source/drain recess and in contact with sidewalls of the first plurality of channel layers, depositing a first contact etch stop layer (CESL) and a first interlayer dielectric (ILD) layer over the n-type source/drain feature, depositing an etch stop layer (ESL) over and in contact with the first CESL and the first ILD layer, forming a p-type epitaxial feature over the ESL and in contact with sidewalls of the second plurality of channel layers, oxidizing the p-type epitaxial feature to form a surface oxide layer, selectively removing the surface oxide layer to form a p-type source/drain feature, and depositing a second CESL and a second ILD layer over the n-type source/drain feature.

In some embodiments, the first CESL and the second CESL include silicon nitride or silicon oxynitride, the ESL includes silicon nitride, and the first ILD layer and the second ILD layer include silicon oxide. In some implementations, a volume of the p-type epitaxial feature is greater than a volume of the n-type source/drain feature and a volume of the p-type source/drain feature is equal to or smaller than the volume of the n-type source/drain feature. In some instances, the oxidizing includes annealing the p-type epitaxial feature in presence of an oxygen source. In some instances, a germanium content of the first plurality of sacrificial layers and the second plurality of sacrificial layers is smaller than a germanium content of the middle silicon germanium layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a stack over a substrate, the stack comprising a plurality of channel layers interleaved by a plurality of sacrificial layers;
patterning the stack and a portion of the substrate to form a first fin-shaped structure and a second fin-shaped structure, the first fin-shaped structure comprising a first base portion formed from the substrate and a first stack portion formed from the stack, the second fin-shaped structure comprising a second base portion formed from the substrate and a second stack portion formed from the stack;
forming an isolation feature over the substrate to interface sidewalls of the first base portion and the second base portion;
forming a dummy gate stack over channel regions of the first fin-shaped structure and the second fin-shaped structure;
recessing source/drain regions of the first fin-shaped structure and the second fin-shaped structure to form a first source/drain recess over the first fin-shaped structure and a second source/drain recess over the second fin-shaped structure;
forming a first mask layer over the second source/drain recess;
with the first mask layer covering the second source/drain recess, depositing a first source/drain feature over the first source/drain recess;
removing the first mask layer;
forming a second mask layer over the first source/drain feature;
with the first source/drain feature covered by the second mask layer, depositing a second source/drain feature over the second source/drain recess;
performing an anneal process in presence of an oxygen source to form a surface oxide layer over the second source/drain feature;
selectively removing the surface oxide layer to form a modified second source/drain feature;
after the selectively removing, removing the second mask layer;
forming a contact etch stop layer (CESL) over the first source/drain feature and the modified second source/drain feature;
removing the dummy gate stack;
selectively removing the plurality of sacrificial layers over the channel regions to form first channel members over the first base portion and second channel members over the second base portion; and
forming a first gate structure to wrap around the first channel members and a second gate structure to wrap around the second channel members,
wherein a composition of the first source/drain feature is different from a composition of the second source/drain feature.

2. The method of claim 1, wherein, after the forming of the isolation feature, a top surface of the isolation feature is lower than a top surface of the first base portion or a top surface of the second base portion.

3. The method of claim 1, wherein the first mask layer and the second mask layer comprise polysulfones, polyureas, polyurea sulfones, polyacrylates, poly(vinyl pyridine), or a silicon-containing polymer.

4. The method of claim 1, wherein the first source/drain feature comprises silicon and an n-type dopant.

5. The method of claim 1, wherein the second source/drain feature comprises silicon germanium and a p-type dopant.

6. The method of claim 1, wherein, after the forming of the second source/drain feature, a thickness of the second source/drain feature is greater than a thickness of the first source/drain feature.

7. The method of claim 1, wherein the oxygen source comprises oxygen or water vapor.

8. The method of claim 1, wherein the anneal process comprises an anneal temperature between about 800° C. and about 1100° C.

9. The method of claim 1, wherein after the selectively removing the surface oxide layer, the modified second source/drain feature comprises a germanium-rich layer.

10. The method of claim 9, wherein the germanium-rich layer has a thickness between about 10 Å and about 20 Å.

11. A method, comprising:
forming a stack over a substrate, the stack comprising a plurality of channel layers interleaved by a plurality of sacrificial layers;
patterning the stack and a portion of the substrate to form a first fin-shaped structure and a second fin-shaped structure, the first fin-shaped structure comprising a first base portion formed from the substrate and a first stack portion formed from the stack, the second fin-shaped structure comprising a second base portion formed from the substrate and a second stack portion formed from the stack;
forming an isolation feature over the substrate to interface sidewalls of the first base portion and the second base portion;
forming a dummy gate stack over channel regions of the first fin-shaped structure and the second fin-shaped structure;
recessing source/drain regions of the first fin-shaped structure and the second fin-shaped structure to form a first source/drain recess over the first fin-shaped structure and a second source/drain recess over the second fin-shaped structure;
forming a first mask layer over the second source/drain recess;
with the first mask layer covering the second source/drain recess, depositing a first source/drain feature over the first source/drain recess;
removing the first mask layer;
forming a second mask layer over the first source/drain feature;
with the first source/drain feature covered by the second mask layer, depositing a second source/drain feature over the second source/drain recess;
performing an anneal process in presence of an oxygen source to form a surface oxide layer over the second source/drain feature;
selectively removing the surface oxide layer to form a modified second source/drain feature;
after the selectively removing, removing the second mask layer;
forming a contact etch stop layer (CESL) over the first source/drain feature and the modified second source/drain feature;
removing the dummy gate stack;
selectively removing the plurality of sacrificial layers over the channel regions to form first channel members over the first base portion and second channel members over the second base portion; and
forming a first gate structure to wrap around the first channel members and a second gate structure to wrap around the second channel members,
wherein the first source/drain feature comprises silicon and an n-type dopant,
wherein the second source/drain feature comprises silicon germanium and a p-type dopant.

12. The method of claim 11, wherein, after the forming of the isolation feature, a top surface of the isolation feature is lower than a top surface of the first base portion or a top surface of the second base portion.

13. The method of claim 11, wherein, after the forming of the second source/drain feature, a thickness of the second source/drain feature is greater than a thickness of the first source/drain feature.

14. The method of claim 11, wherein the oxygen source comprises oxygen or water vapor.

15. The method of claim 11, wherein the anneal process comprises an anneal temperature between about 800° C. and about 1100° C.

16. The method of claim 11, wherein after the selectively removing the surface oxide layer, the modified second source/drain feature comprises a germanium-rich layer.

17. The method of claim 16, wherein the germanium-rich layer has a thickness between about 10 Å and about 20 Å.

18. A method, comprising:
forming a stack over a substrate, the stack comprising a plurality of channel layers interleaved by a plurality of sacrificial layers;
patterning the stack and a portion of the substrate to form a first fin-shaped structure and a second fin-shaped structure, the first fin-shaped structure comprising a first base portion formed from the substrate and a first stack portion formed from the stack, the second fin-shaped structure comprising a second base portion formed from the substrate and a second stack portion formed from the stack;
forming an isolation feature over the substrate to interface sidewalls of the first base portion and the second base portion;
forming a dummy gate stack over channel regions of the first fin-shaped structure and the second fin-shaped structure;
recessing source/drain regions of the first fin-shaped structure and the second fin-shaped structure to form a first source/drain recess over the first fin-shaped structure and a second source/drain recess over the second fin-shaped structure;
forming a first mask layer over the second source/drain recess;
with the first mask layer covering the second source/drain recess, depositing a first source/drain feature over the first source/drain recess;
removing the first mask layer;
forming a second mask layer over the first source/drain feature;
with the first source/drain feature covered by the second mask layer, depositing a second source/drain feature over the second source/drain recess;
performing an anneal process in presence of an oxygen source to form a surface oxide layer over the second source/drain feature;
selectively removing the surface oxide layer to form a modified second source/drain feature;
after the selectively removing, removing the second mask layer;
forming a contact etch stop layer (CESL) over the first source/drain feature and the modified second source/drain feature;
removing the dummy gate stack;
selectively removing the plurality of sacrificial layers over the channel regions to form first channel members over the first base portion and second channel members over the second base portion; and
forming a first gate structure to wrap around the first channel members and a second gate structure to wrap around the second channel members,
wherein the first source/drain feature comprises silicon and an n-type dopant,
wherein the second source/drain feature comprises silicon germanium and a p-type dopant,
wherein, after the forming of the second source/drain feature, a thickness of the second source/drain feature is greater than a thickness of the first source/drain feature.

19. The method of claim 18, wherein after the selectively removing the surface oxide layer, the modified second source/drain feature comprises a germanium-rich layer.

20. The method of claim 19, wherein the germanium-rich layer has a thickness between about 10 Å and about 20 Å.
